(19) United States
(12) Patent Application Publication
(10) Pub. No.: US 2008/0132053 A1
(43) Pub. Date: Jun. 5, 2008

(54) Method for Preparing an Intergrated Circuits Device Having a Reinforcement Structure

(75) Inventors: Hsiao Che Wu, Taoyuan County (TW); Yu Min Tsai, Taichung County (TW); Wen Li Tsai, Kaohsiung County (TW)

Correspondence Address: WPAT, PC;INTELLECTUAL PROPERTY ATTORNEYS, 2030 MAIN STREET, SUITE 1300, IRVINE, CA, 92614, US

(73) Assignee: PROMOS TECHNOLOGIES INC., Hsinchu (TW)

(21) Appl. No.: 11/566,166

(22) Filed: Dec. 1, 2006

(51) Int. Cl. H01L 21/44

(52) U.S. Cl. 438/612; 257/E21.476

(57) ABSTRACT

An integrated circuit device comprises a substrate, a stack structure including circuit structure having conductive lines positioned on the substrate, a reinforcement structure including at least one supporting member positioned on the substrate and a roof covering the circuit structure and the supporting member and at least one bonding pad positioned on the roof and electrically connected to the conductive lines. A method for preparing an integrated circuit device comprises forming a stack structure including circuit structure having conductive lines on a substrate, forming a reinforcement structure including at least one supporting member on the substrate and a roof covering the supporting member and the circuit structure and forming at least one bonding pad on the roof and electrically connecting to the conductive lines.

### BACKGROUND OF THE INVENTION

(A) Field of the Invention

The present invention relates to a method for preparing an integrated circuit device having a reinforcement structure, and more particularly, to a method for preparing an integrated circuit device having a circuit structure with low fracture toughness and a reinforcement structure for preventing the circuit structure from collapsing.

(B) Description of the Related Art

As the size of the integrated circuit device shrinks, the employing of more conductive material as interconnects and lower dielectric constant (low-k) material as inter-metal/inter-layer dielectrics is imperative. In addition, to reduce power consumption, time delay, crosstalk level and delay caused by crosstalk, the ultra low-k/Cu stack is used for fabricating logic devices.

FIG. 1 shows the relationship between the hardness and the dielectric constant of low-k dielectric material. The hardness of the low-k dielectric material decreases as the dielectric constant decreases. Consequently, the low-k dielectric material in the low-k/Cu stack has the disadvantage of low fracture toughness, which can lead to yield loss during the pad bonding process performed after the fabrication process of the circuit structure.

### SUMMARY OF THE INVENTION

One aspect of the present invention provides a method for preparing an integrated circuit device having a circuit structure with low fracture toughness and a reinforcement structure for preventing the circuit structure from collapsing.

A method for preparing an integrated circuit device according to this aspect of the present invention comprises the steps of forming a stack structure including a circuit structure having conductive lines therein on a substrate, forming a reinforcement structure including at one supporting member in the stack structure and a roof covering the supporting member and the circuit structure and forming at least one bonding pad on the roof and electrically connected to the conductive lines of the circuit structure.

According to the prior art, the stack structure of Cu/low-k dielectric material has the disadvantage of low fracture toughness, which can lead to yield loss during the pad bonding process performed after the fabrication process of the stack structure. In contrast, the present integrated circuit device comprises the reinforcement structure including the supporting member on the substrate and the roof covering the circuit structure and the supporting member such that the downward force by the pad bonding process can be dispersed to prevent the circuit structure from collapsing and thus reduces the possibility of stress-induced failure.

### BRIEF DESCRIPTION OF THE DRAWINGS

The objectives and advantages of the present invention will become apparent upon reading the following description and upon reference to the accompanying drawings in which:

FIG. 1 shows the relationship between the hardness and the dielectric constant of the low-k dielectric material;

FIG. 2 and FIG. 3 illustrate an integrated circuit device according to the first embodiment of the present invention;

FIG. 4 and FIG. 5 illustrate an integrated circuit device according to the second embodiment of the present invention;

FIG. 6 and FIG. 7 illustrate an integrated circuit device according to the third embodiment of the present invention;

FIG. 8 to FIG. 17 illustrate a method for preparing an integrated circuit device according to the first embodiment of the present invention;

FIG. 18 to FIG. 26 illustrate a method for preparing an integrated circuit device according to the second embodiment of the present invention;

FIG. 27 to FIG. 36 illustrate a method for preparing an integrated circuit device according to the third embodiment of the present invention;

FIG. 37 to FIG. 46 illustrate a method for preparing an integrated circuit device according to the fourth embodiment of the present invention;

FIG. 47 to FIG. 54 illustrate a method for preparing an integrated circuit device according to the fifth embodiment of the present invention; and

FIG. 55 to FIG. 61 illustrate a method for preparing an integrated circuit device according to the sixth embodiment of the present invention.

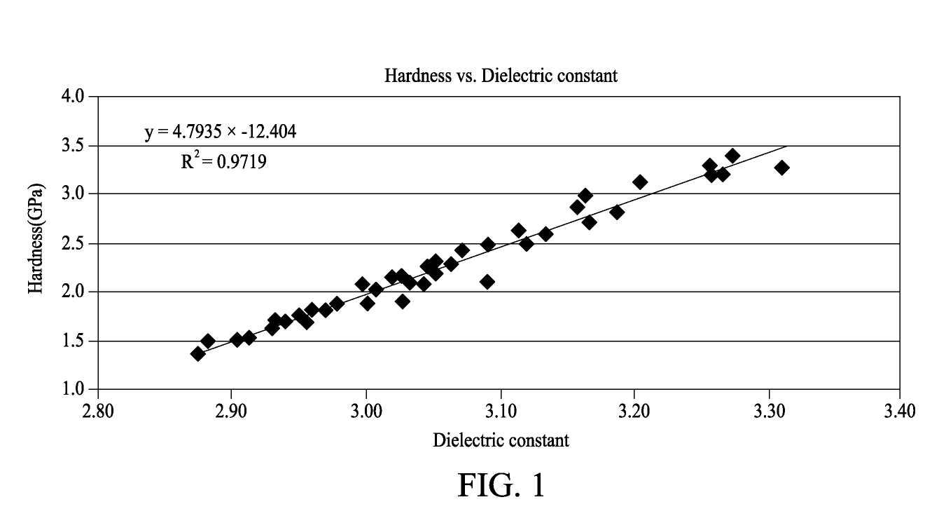

### DETAILED DESCRIPTION OF THE INVENTION

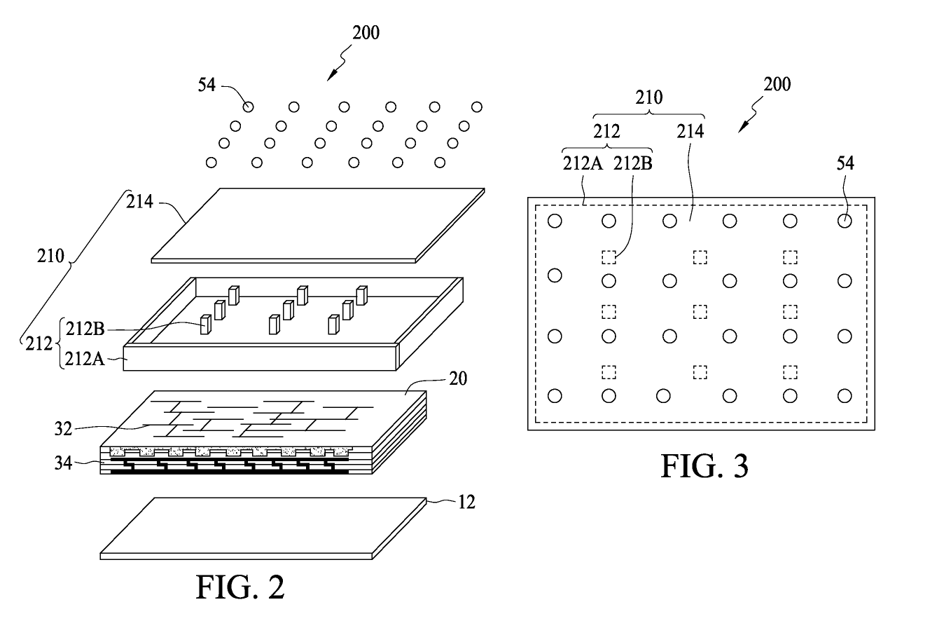

FIG. 2 and FIG. 3 illustrate an integrated circuit device 200 according to is the first embodiment of the present invention, wherein FIG. 2 is exploded view and FIG. 3 is a top view of the integrated circuit device 200. The integrated circuit device 200 comprises a substrate 12, a circuit structure 20 including conductive lines 32 and insulation layers 34 positioned on the substrate 12, a reinforcement structure 210 including at least one supporting member 212 positioned on the substrate 12 and a roof 214 covering the circuit structure 20 and the supporting member 212 and a plurality of bonding pads 54 positioned on the roof 214 and electrically connected to the conductive lines 32 in the circuit structure 20.

The substrate 12 can be a silicon wafer, a polysilicon wafer, a silicon-germanium wafer, a silicon-on-insulator wafer or silicon-on-nothing wafer. The conductive lines 32 can be made of polysilicon or metal. The polysilicon can be p-type polysilicon or n-type polysilicon, and the metal can be selected from the group consisting essentially of tungsten silicide, cobalt silicide, nickel silicide, tantalum silicide, titanium silicide, aluminum silicide, tungsten, tungsten nitride, titanium, titanium nitride, tantalum, tantalum nitride, aluminum, aluminum-copper alloy, aluminum-silicon-copper alloy, aluminum-silicon alloy, ruthenium, copper, copper-zinc alloy, zirconium, platinum, iridium and the combination thereof. In addition, the insulation layers 34 can be made of dielectric material selected from the group consisting essentially of silicon oxide, silicon nitride, strontium oxide, silicon-oxy-nitride, undoped silicate glass, fluorinated silicate glass, low-k material with a dielectric constant between 2.5 and 3.9, ultra low-k material with a dielectric constant smaller than 2.5 and the combination thereof.

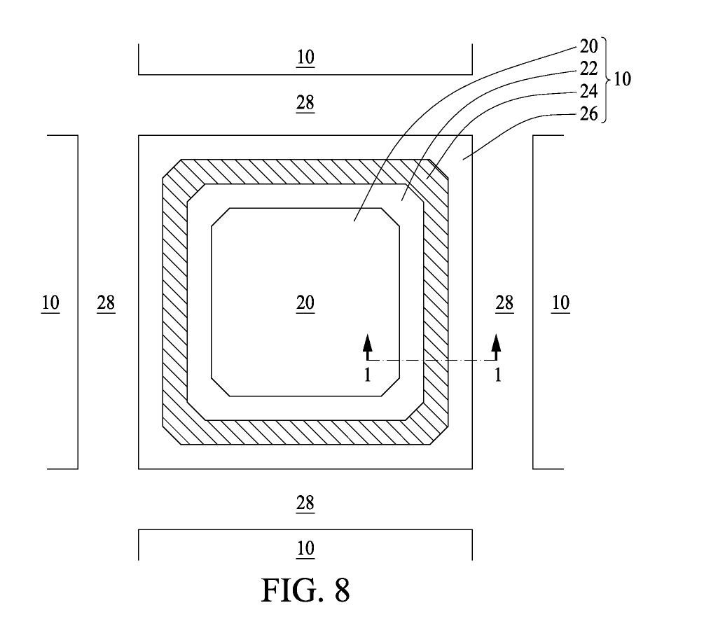

The supporting member 212 includes a ring-shaped wall 212A positioned on the substrate 12 and a plurality of pillars 212B positioned in the circuit structure 20. Preferably, the pillars 212B can be positioned in an array manner, in a symmetrical manner or in an asymmetrical manner. Furthermore, the pillars 212B can be elliptical, square, polygonal, star-shaped, donut-shaped, triangular, bar-shaped or arrow-shaped. In addition, the wall 212A can be positioned at the edge of the integrated circuit device 200, between a die seal 24 and the circuit structure 20 or between a die seal 24 and a scrape line 28, as shown in FIG. 8.

The supporting member 212 can be made of dielectric material, conductive material or the combination thereof, wherein the dielectric material is selected from the group consisting essentially of silicon oxide, silicon nitride, strontium oxide, silicon-oxy-nitride, undoped silicate glass and fluorinated silicate glass, and the conductive material is polysilicon or metal. The polysilicon is p-type polysilicon, n-type polysilicon or undoped polysilicon. The metal is selected from the group consisting essentially of tungsten silicide, cobalt silicide, nickel silicide, tantalum silicide, titanium silicide, aluminum silicide, tungsten, tungsten nitride, titanium, titanium nitride, tantalum, tantalum nitride, aluminum, aluminum-copper alloy, aluminum-silicon-copper alloy, aluminum-silicon alloy, ruthenium, copper, copper-zinc alloy, zirconium, platinum, iridium and the combination thereof.

In addition, the bonding pads 54 can be made of polysilicon or metal. The polysilicon is p-type polysilicon or n-type polysilicon, and the metal is selected from the group consisting essentially of tungsten silicide, cobalt silicide, nickel silicide, tantalum silicide, titanium silicide, aluminum silicide, tungsten, tungsten nitride, titanium, titanium nitride, tantalum, tantalum nitride, aluminum, aluminum-copper alloy, aluminum-silicon-copper alloy, aluminum-silicon alloy, ruthenium, copper, copper-zinc alloy, zirconium, platinum, iridium, silver, gold, nickel, nickel-vanadium alloy, lead, stannum and the combination thereof.

According to the prior art, the stack structure of Cu/low-k dielectric material has the disadvantage of low fracture toughness, which can lead to yield loss during the pad bonding process performed after the fabrication process of the stack structure. In contrast, the present integrated circuit device 200 comprises the reinforcement structure 210 including the supporting member 212 on the substrate 12 and the roof 214 covering the circuit structure 20 and the supporting member 212 such that the downward force by the pad bonding process can be dispersed to prevent the circuit structure 20 from collapsing and thus reduces the possibility of stress-induced failure.

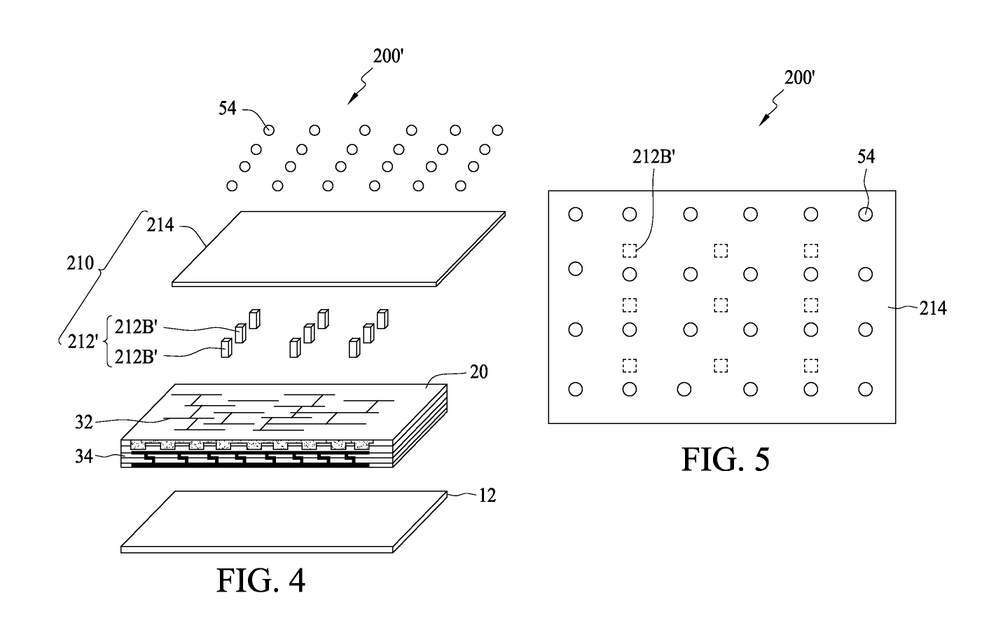

FIG. 4 and FIG. 5 illustrate an integrated circuit device 200′ according to the second embodiment of the present invention, wherein FIG. 4 is an exploded view and FIG. 5 is a top view of the integrated circuit device 200′. In comparison with the integrated circuit device 200 shown in FIG. 2 having the supporting member 212 include a ring-shaped wall 212A and a plurality of pillars 212B, the supporting member 212′ of the integrated circuit device 200′ includes the pillars 212B′ in the circuit structure 20, and no ring-shaped wall.

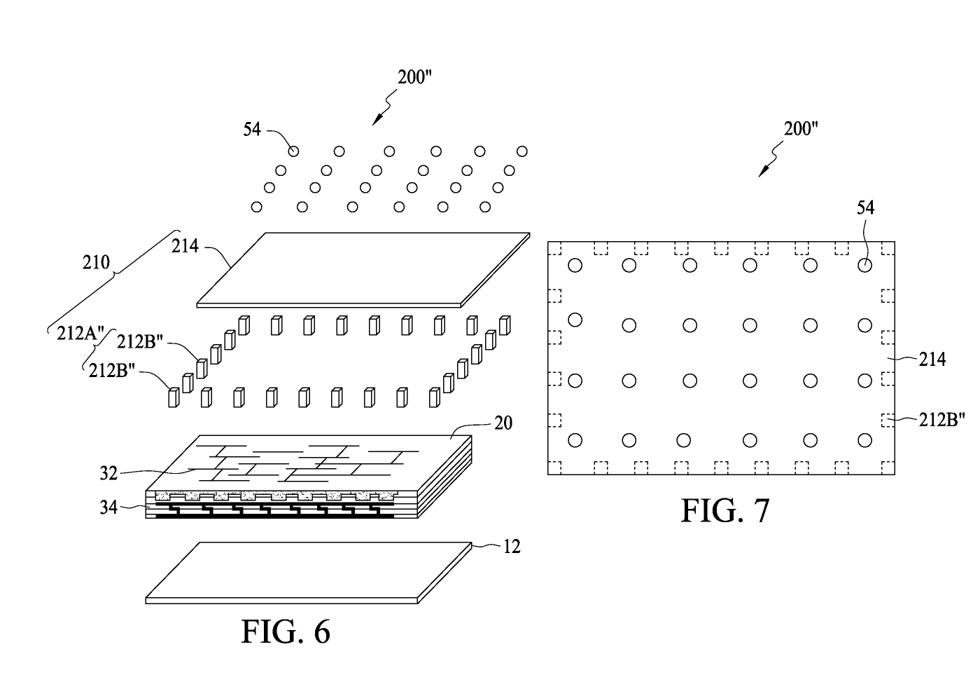

FIG. 6 and FIG. 7 illustrate an integrated circuit device 200″ according to the third embodiment of the present invention, wherein FIG. 6 is an exploded view and FIG. 7 is a top view of the integrated circuit device 200″. In comparison with the integrated circuit device 200 shown in FIG. 2 having the supporting member 212 include a ring-shaped wall 212A and a plurality of pillars 212B, the supporting member 212″ of the integrated circuit device 200″ includes a plurality of pillars 212B″ positioned in a ring-shaped manner to form a wall 212A″.

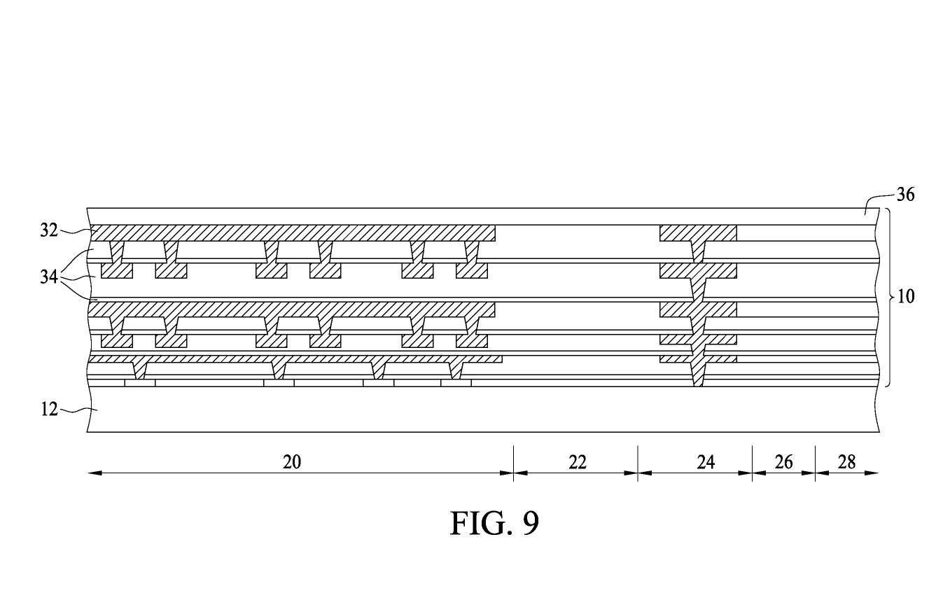

FIG. 8 to FIG. 17 illustrate a method for preparing an integrated circuit device 200 according to the first embodiment of the present invention. FIG. 9 to FIG. 17 are cross-sectional views along a cross-sectional line 1-1 in FIG. 8. First, a plurality of stack structures 10 are formed on a substrate 12 and surrounded by scribe lines 28. Each stack structure 10 includes a circuit structure 20, a first buffer area 22 surrounding the circuit structure 20, a die seal 24 surrounding the first buffer area 22, a second buffer area 26 surrounding the die seal 24 and an oxide layer 36. The circuit structure 20 includes conductive lines 32 and several isolation layers 34 made of dielectric material, as shown in FIG. 9.

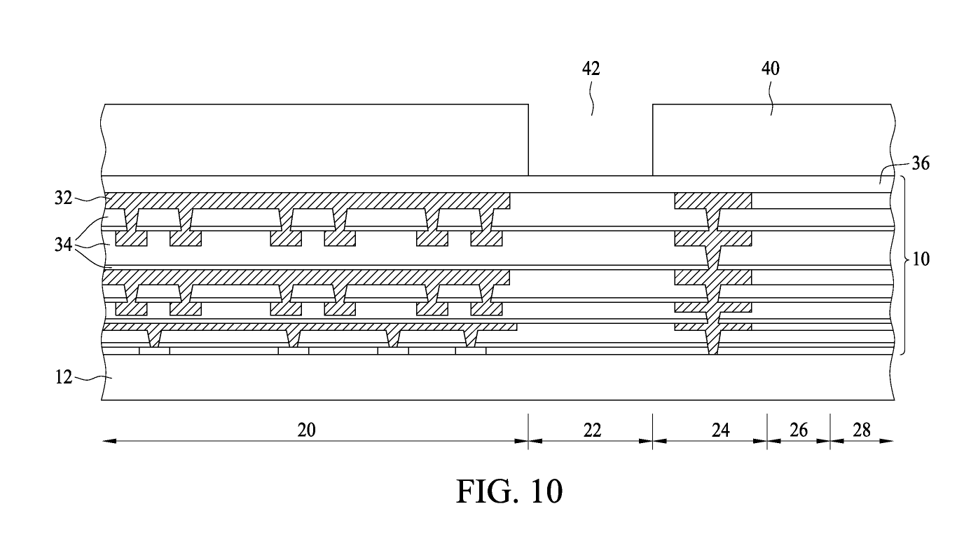

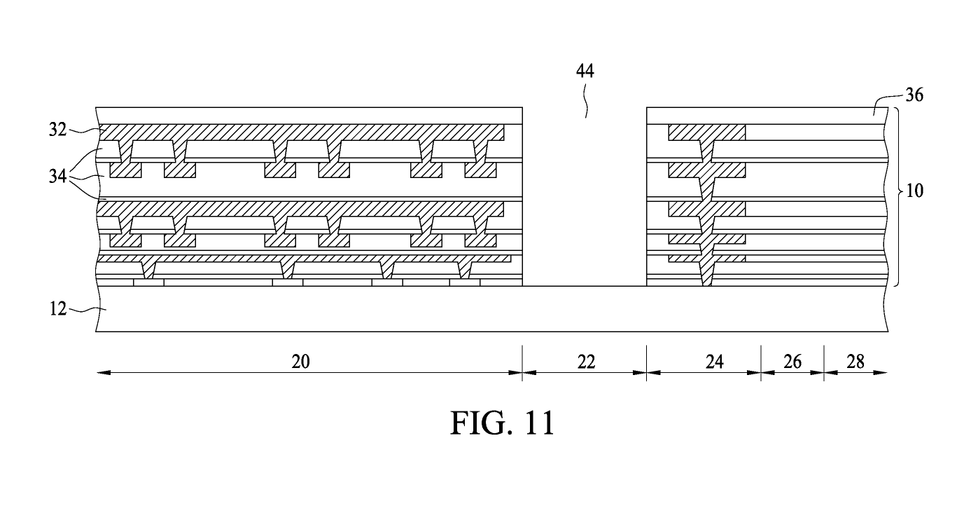

Referring to FIG. 10, an etching mask 40 including at least one aperture 42 is formed on the oxide layer 36, and the aperture 42 exposes the first buffer area 22 between the circuit structure 20 and the die seal 24. The aperture 42 may optionally expose the second buffer area 26 between the die seal 24 and the scribe line 28. In particular, the aperture 42 is used for patterning the size and the position of the supporting member 212 so that the position and the number of the aperture 42 correspond to those of the pillars 212B and the wall 212A of the supporting member 212. An etching process is performed to remove a portion of the stack structure 10 under the aperture 42 down to the surface of the substrate 12 to form at least one opening 44 in the stack structure 10, and the etching mask 40 is then removed, as shown in FIG. 11.

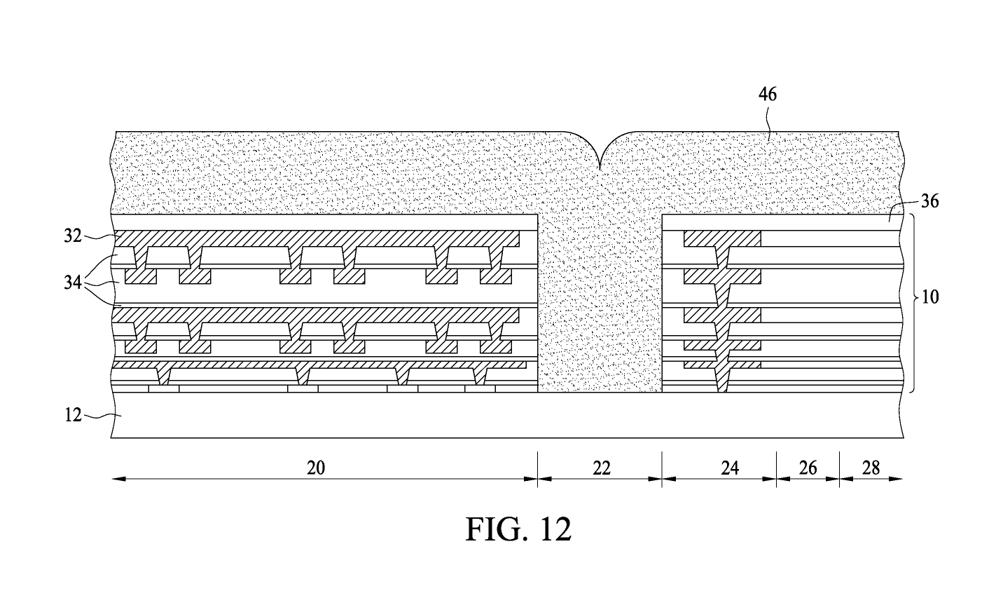

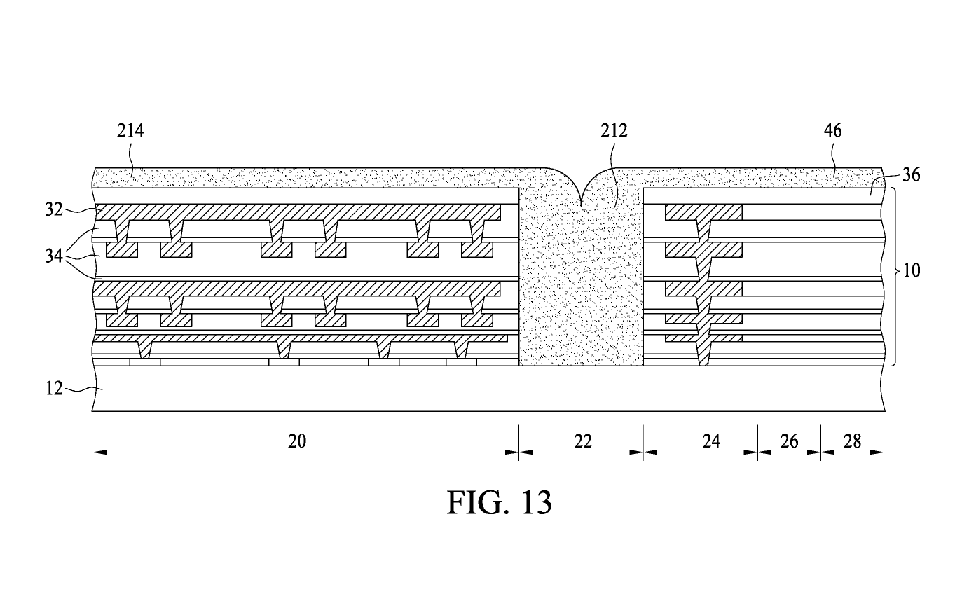

Referring to FIG. 12, a deposition process is performed to form a dielectric layer 46 covering the surface of the oxide layer 36 of the stack structure 10 and filling the opening 44 in the stack structure 10. An etch back process is then performed to reduce the thickness of the dielectric layer 46 on the surface of the oxide layer 36 of the stack structure 10. After the etch back process, the dielectric layer 46 remaining on the surface of the circuit structure 20 serves as the roof 214 and the dielectric layer 46 remaining in the opening 44 serves as the supporting member 212, as shown in FIG. 13.

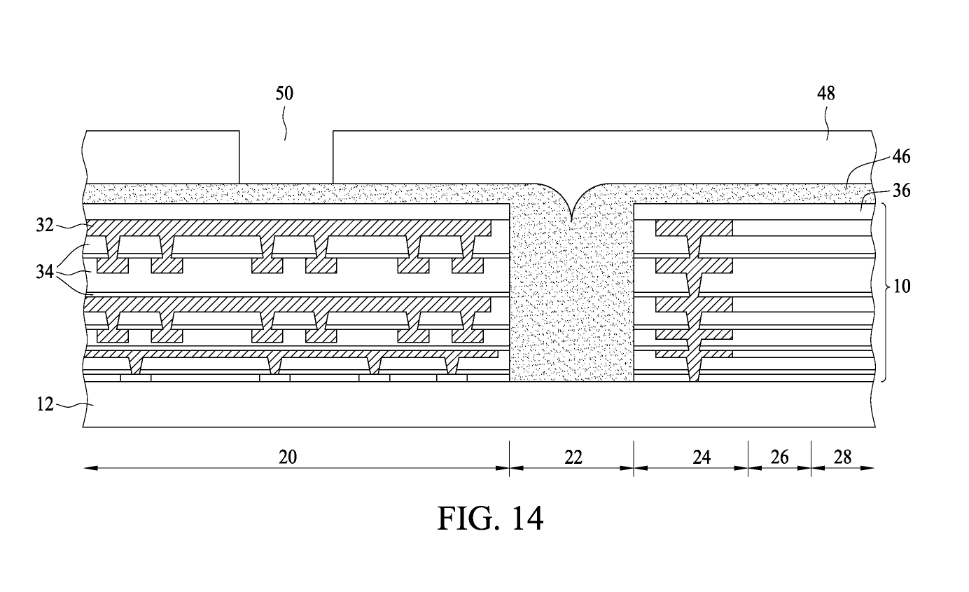

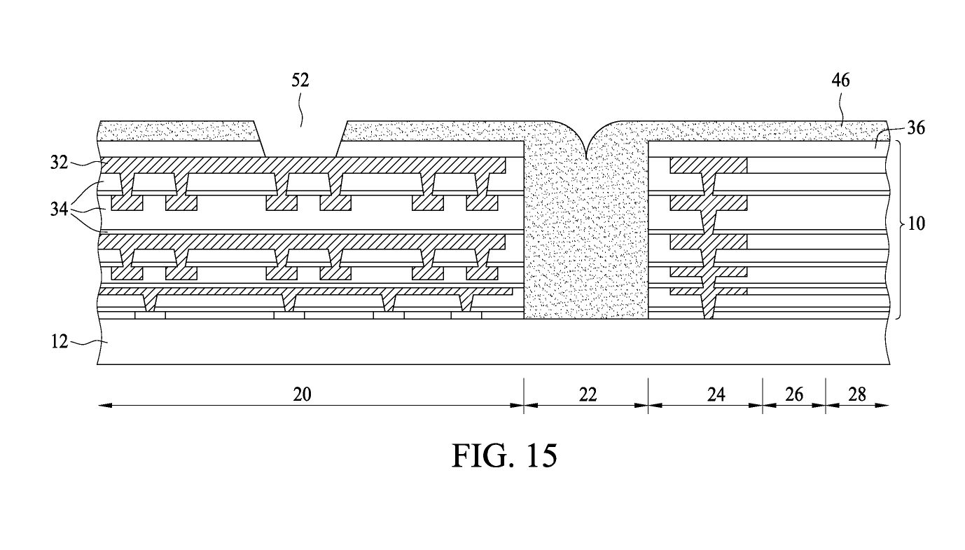

Referring to FIG. 14, an etching mask 48 including at least one aperture 50 is formed on the dielectric layer 46, and the aperture 50 exposes a portion of the dielectric layer 46 on the circuit structure 20, i.e., exposes a portion of the roof 214. In particular, the aperture 50 is used for patterning the size and the position of the bonding pad 54 on the roof 214, and the position and number of the aperture 50 correspond to those of the bonding pad 54. An etching process is performed to remove a portion of the dielectric layer 46, the oxide layer 36 and the circuit structure 20 under the aperture 50 to form at least one opening 52 in the dielectric layer 46, the opening 52 exposes the conductive lines 32 in the circuit structure 20, and the etching mask 48 is then removed, as shown in FIG. 15.

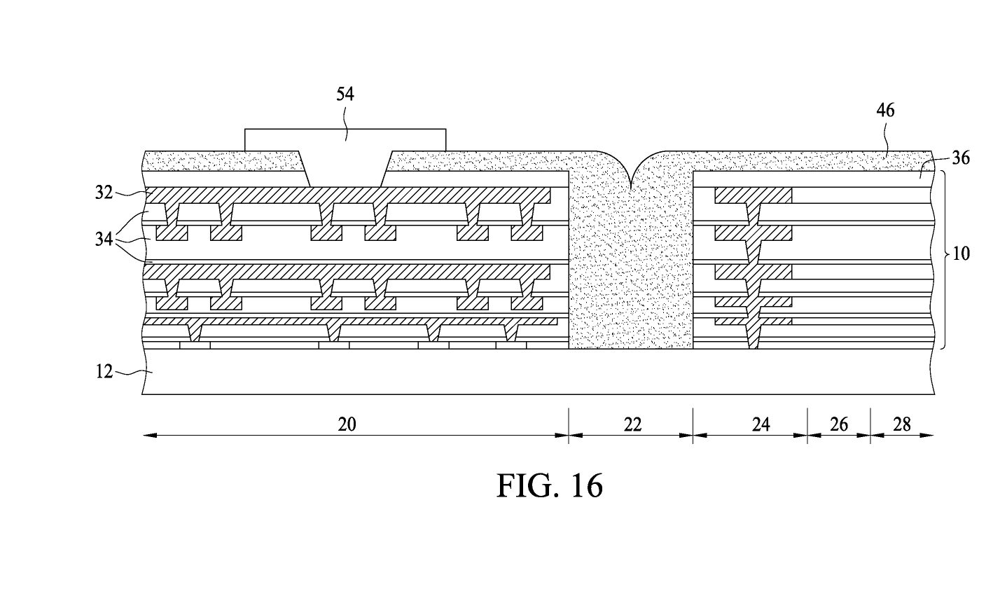

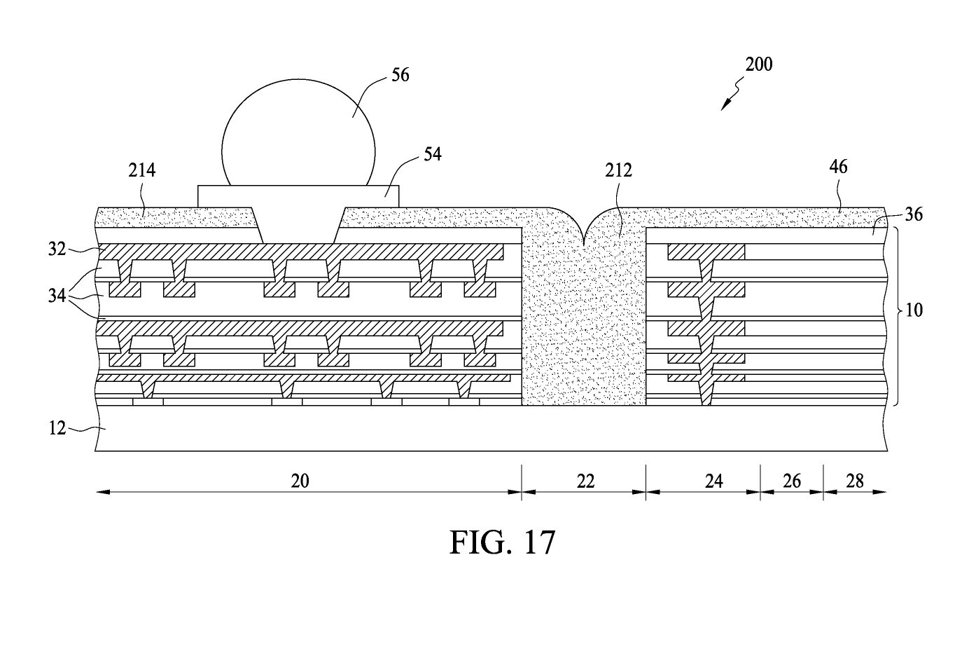

Referring to FIG. 16, a conductive layer (not shown in the drawing) is formed to cover the surface of the dielectric layer 46 and fill the opening 52, and a portion of the conductive layer is removed from the surface of the dielectric layer 46 to form a bonding pad 54 on the dielectric layer 46 that is electrically connected to the conductive lines 32 in the circuit structure 20. Subsequently, a solder ball 56 is formed on the bonding pads 54 to complete the integrated circuit device 200, as shown in FIG. 17.

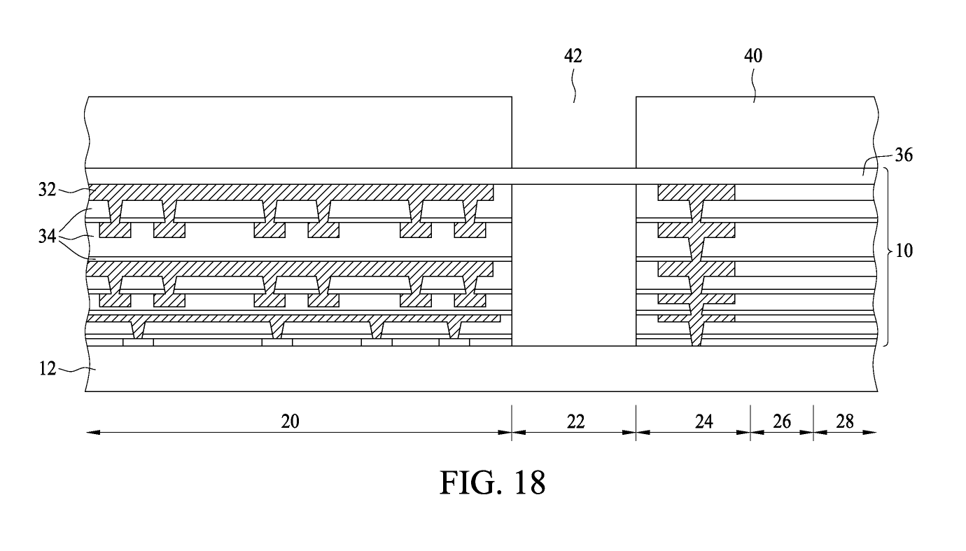

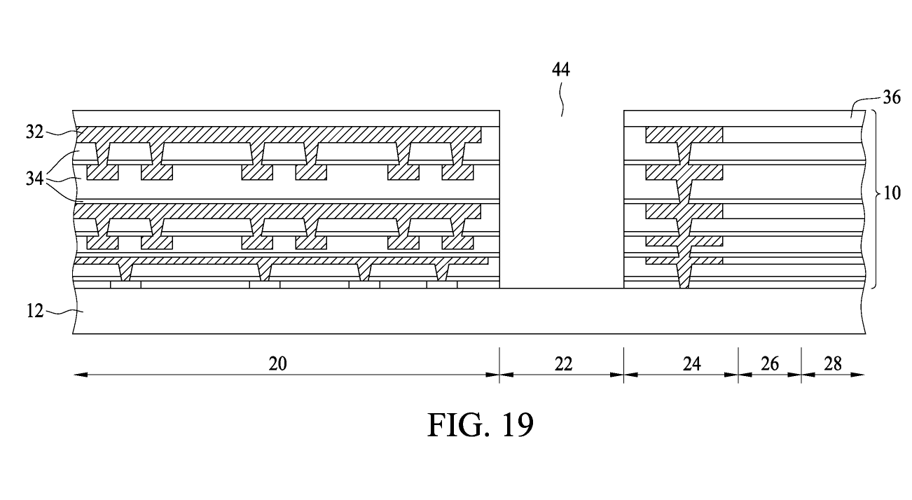

FIG. 18 to FIG. 26 illustrate a method for preparing an integrated circuit device 200 according to the second embodiment of the present invention. FIG. 18 to FIG. 26 are cross-sectional views along a cross-sectional line 1-1 in FIG. 8. An etching mask 40 including at least one aperture 42 is formed on the oxide layer 36, and the aperture 42 exposes the first buffer area 22 between the circuit structure 20 and the die seal 24. An etching process is performed to remove a portion of the stack structure 10 under the aperture 42 down to the surface of the substrate 12 to form at least one opening 44 in the stack structure 10, and the etching mask 40 is then removed, as shown in FIG. 19. In particular, the aperture 42 is used for patterning the size and the position of the supporting member 212 so that the position and the number of the aperture 42 correspond to those of the pillars 212B and the wall 212A of the supporting member 212.

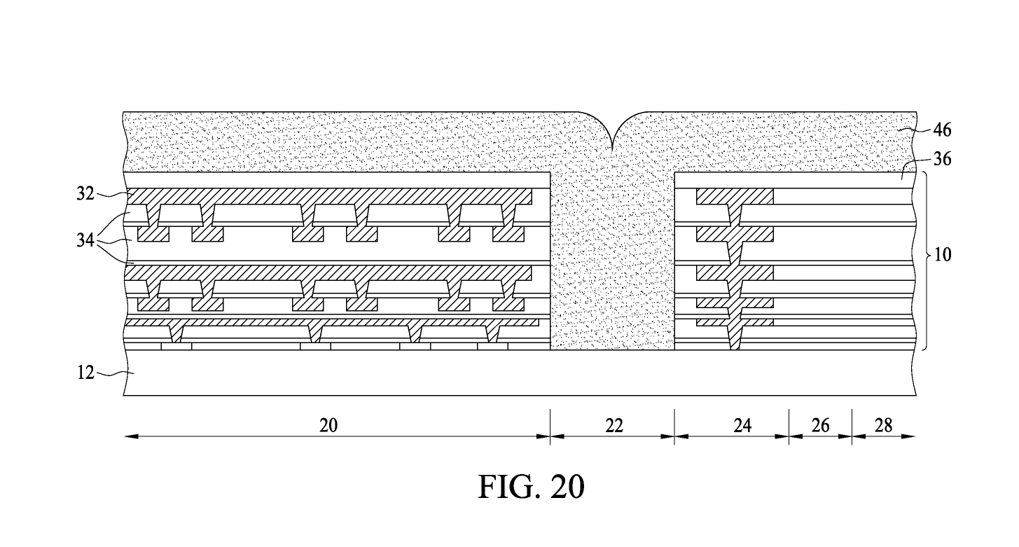

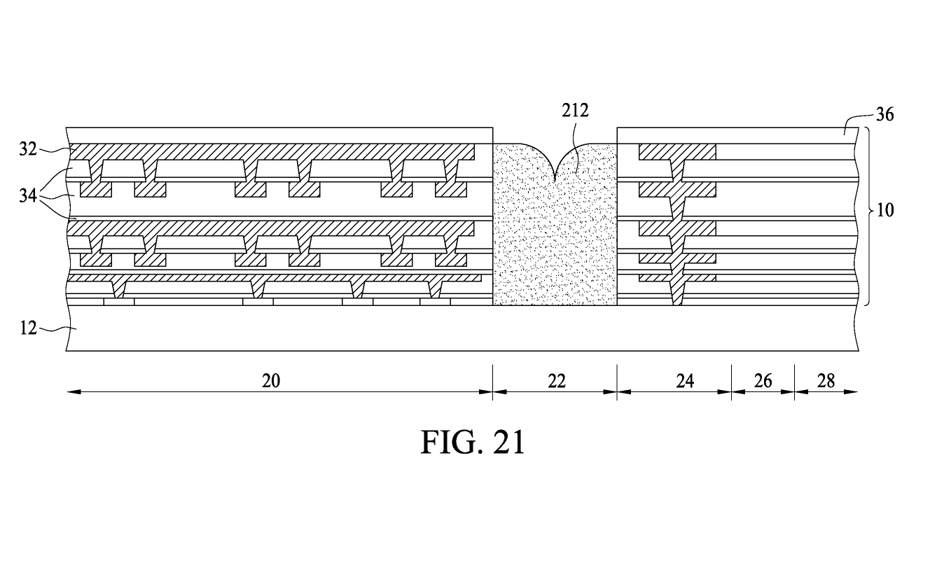

Referring to FIG. 20, a deposition process is performed to form a dielectric layer 46 covering the surface of the oxide layer 36 of the stack structure 10 and filling the opening 44 in the stack structure 10. An etch back process is then performed to remove a portion of the dielectric layer 46 on the surface of the oxide layer 36 completely, while a portion of the dielectric layer 46 in the opening 44 remains after the etch back process. The dielectric layer 46 remaining in the opening 44 serves as the supporting member 212 of the reinforcement structure 210, as shown in FIG. 21.

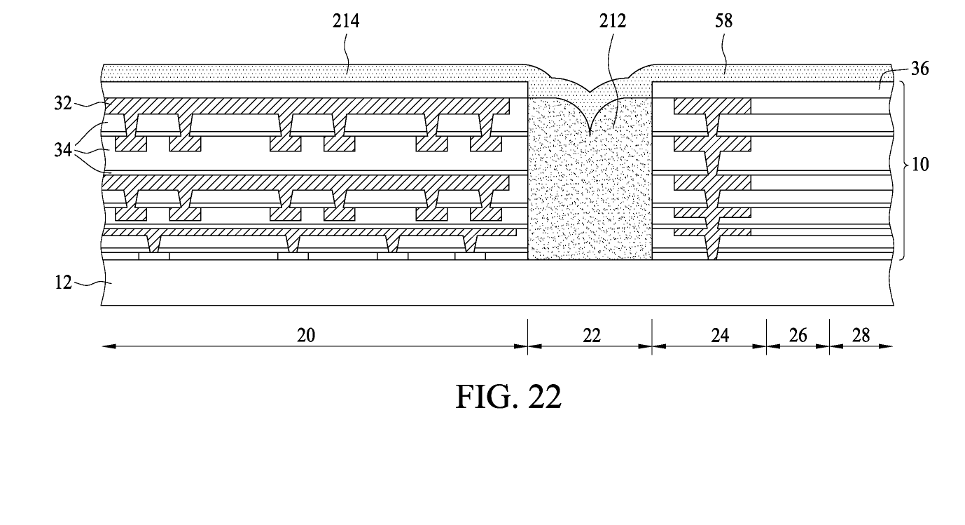

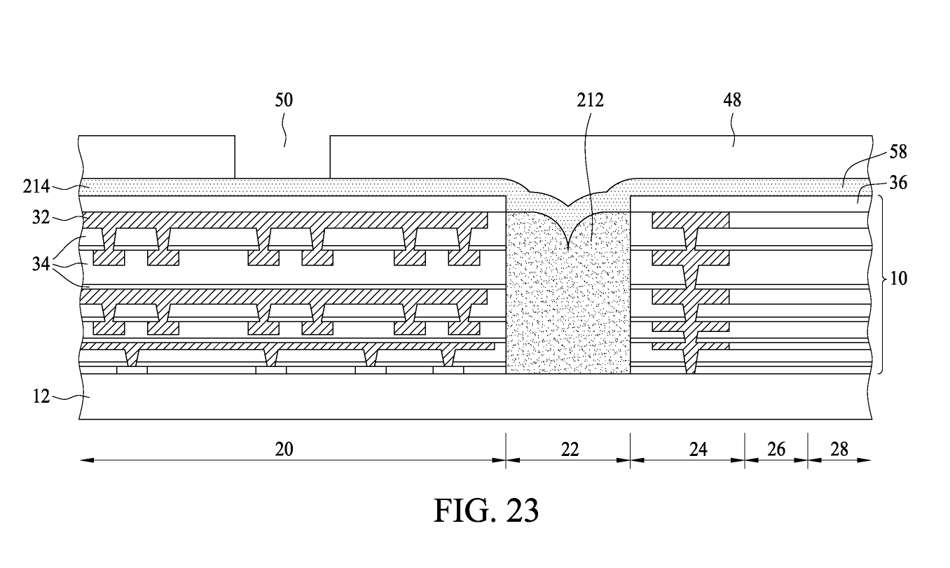

Referring to FIG. 22, a deposition process is performed to form a dielectric layer 58 to cover the surface of the circuit structure 20 and the supporting member 212 in the opening 44, and the dielectric layer 58 on the circuit structure 20 serves as the roof 214 of the reinforcement structure 210. An etching mask 48 including at least one aperture 50 is formed on the dielectric layer 58, and the aperture 50 exposes a portion of the dielectric layer 58 on the circuit structure 20, i.e., exposes a portion of the roof 214, as shown in FIG. 23. In particular, the aperture 50 is used for patterning the size and the position of the bonding pad 54 on the roof 214, and the position and number of the aperture 50 correspond to those of the bonding pad 54.

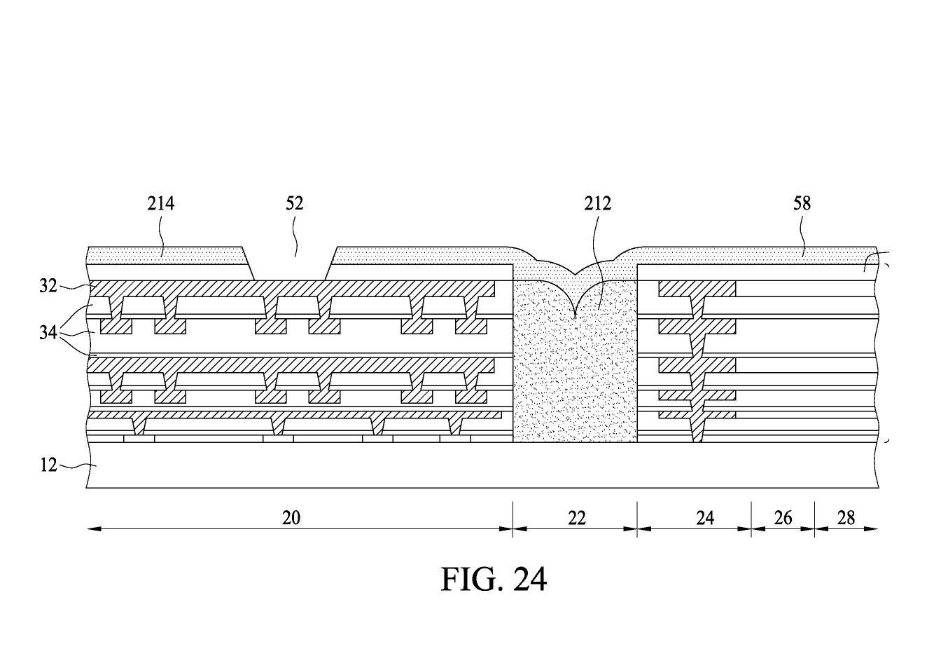

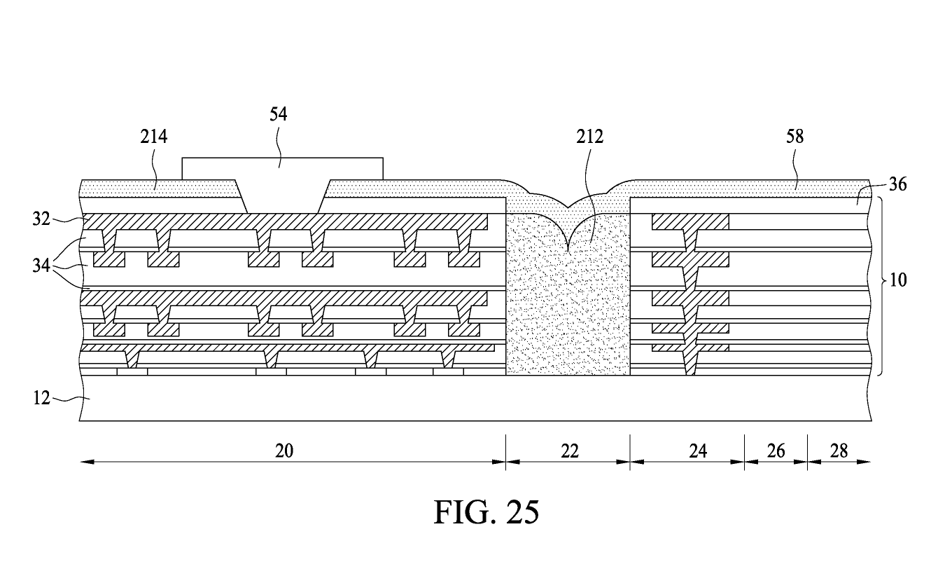

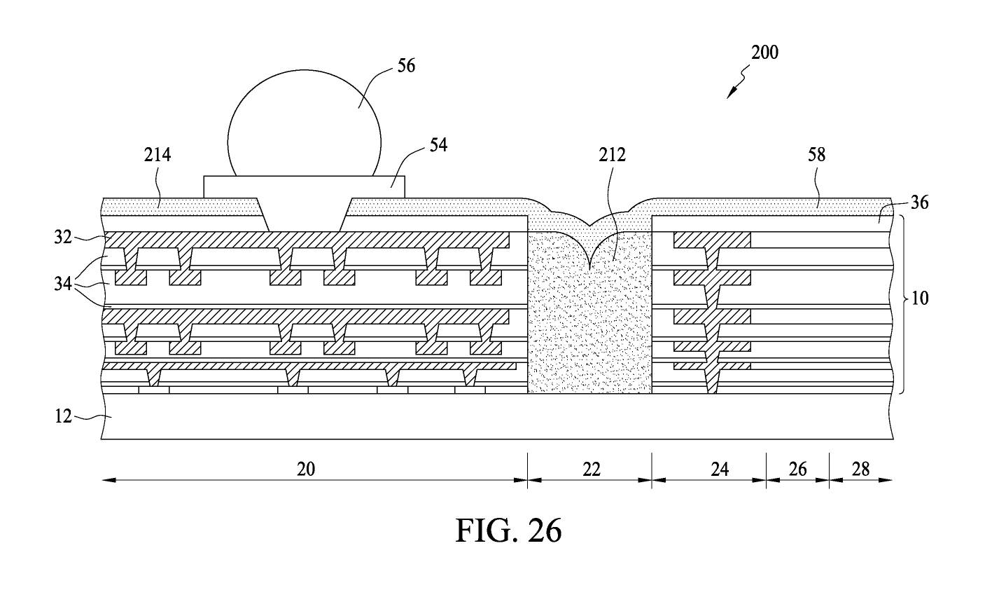

Referring to FIG. 24, an etching process is performed to remove a portion of the dielectric layer 58, the oxide layer 36 and the circuit structure 20 under the aperture 50 to form at least one opening 52 in the dielectric layer 58, the opening 52 exposes the conductive lines 32 in the circuit structure 20, and the etching mask 48 is then removed. A deposition process is performed to form a conductive layer (not shown in the drawing) covering the surface of the dielectric layer 58 and filling the opening 52, and a portion of the conductive layer is removed from the surface of the dielectric layer 58 to form the bonding pad 54 on the roof 214, as shown in FIG. 25. Subsequently, a solder ball 56 is formed on the bonding pads 54 to complete the integrated circuit device 200, as shown in FIG. 26.

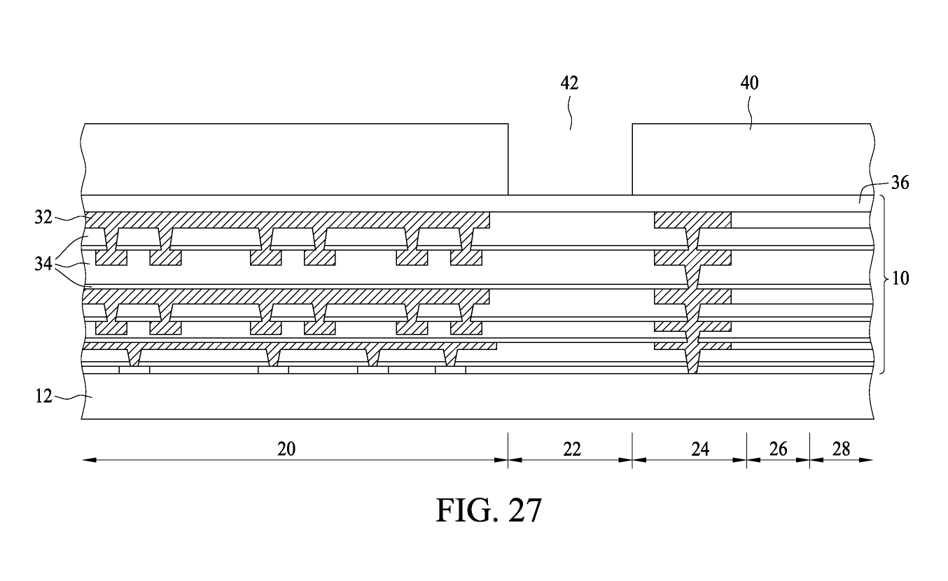

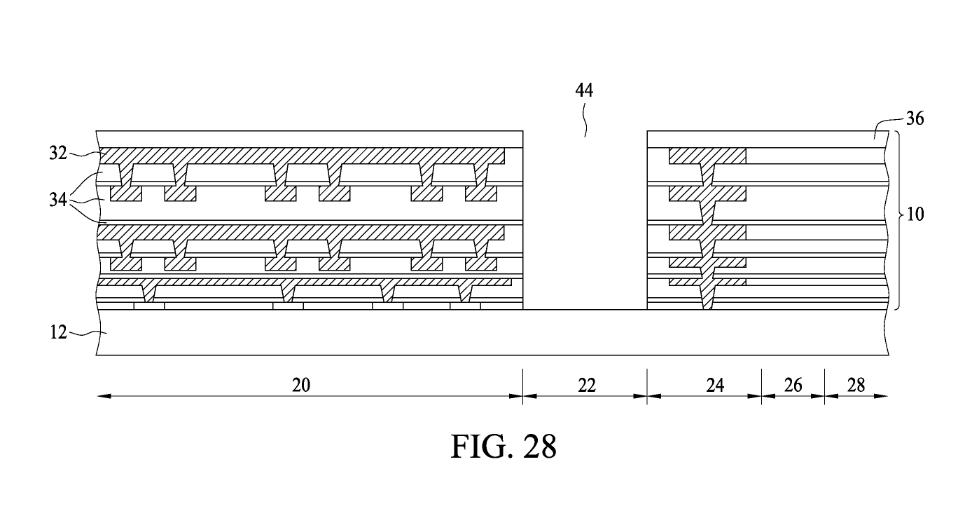

FIG. 27 to FIG. 36 illustrate a method for preparing an integrated circuit device 200 according to the third embodiment of the present invention. FIG. 27 to FIG. 36 are cross-sectional views along a cross-sectional line 1-1 in FIG. 8. An etching mask 40 including at least one aperture 42 is formed on the oxide layer 36, and the aperture 42 exposes the first buffer area 22 between the circuit structure 20 and the die seal 24. An etching process is performed to remove a portion of the stack structure 10 under the aperture 42 down to the surface of the substrate 12 to form at least one opening 44 in the stack structure 10, and the etching mask 40 is then removed, as shown in FIG. 28. In particular, the aperture 42 is used for patterning the size and the position of the supporting member 212 so that the position and the number of the aperture 42 correspond to those of the pillars 212B and the wall 212A of the supporting member 212.

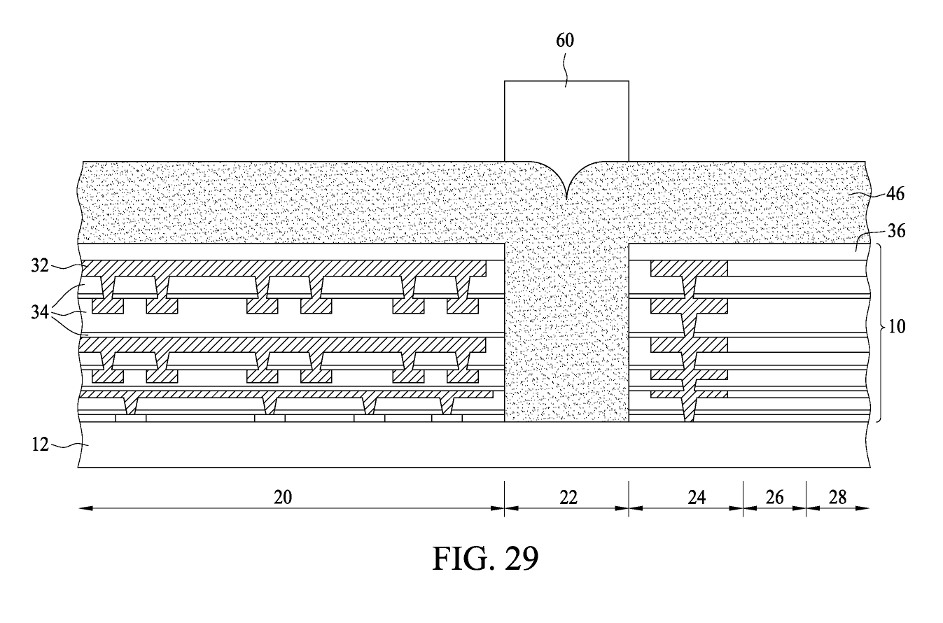

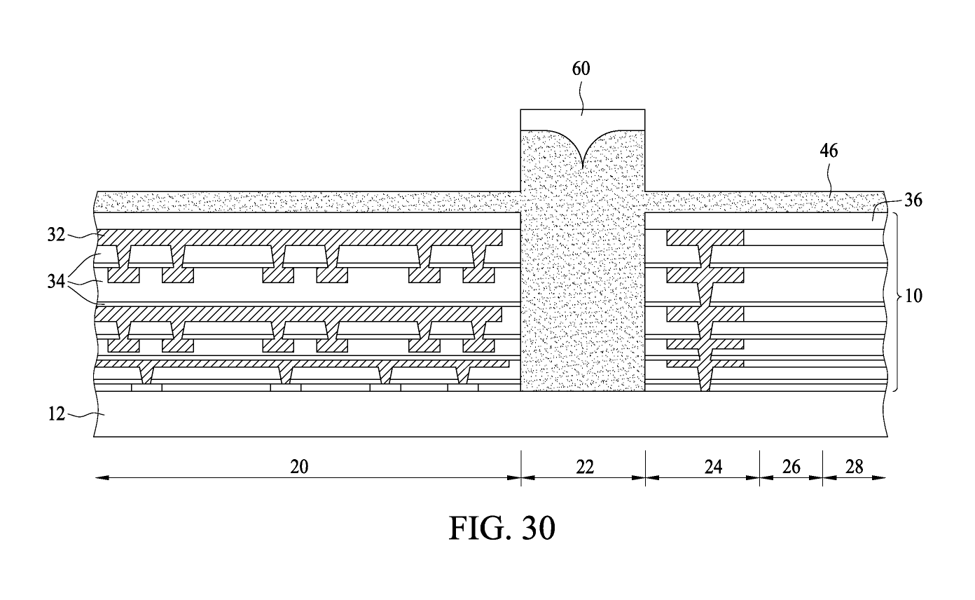

Referring to FIG. 29, a deposition process is performed to form a dielectric layer 46 covering the surface of the oxide layer 36 of the stack structure 10 and filling the opening 44 in the stack structure 10, and an etching mask 60 is formed to cover a portion of the dielectric layer 46 on the opening 44. Subsequently, a dry etching process is performed to remove a portion of the dielectric layer 46 not covered by the etching mask 60, as shown in FIG. 30.

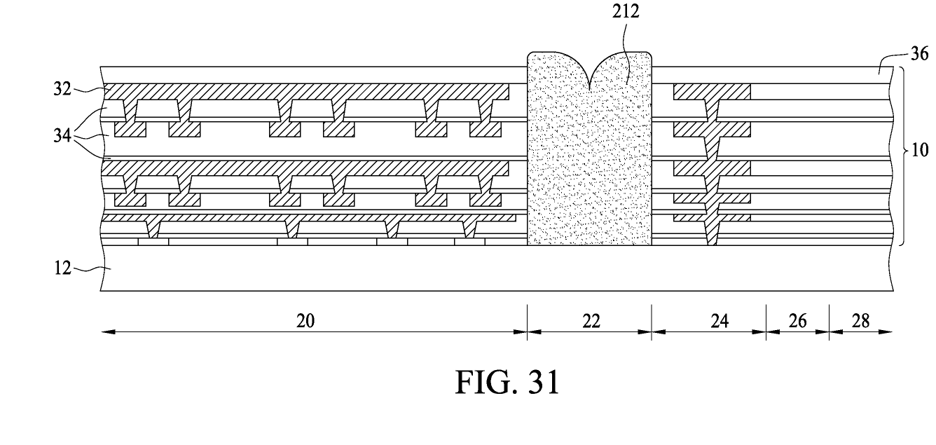

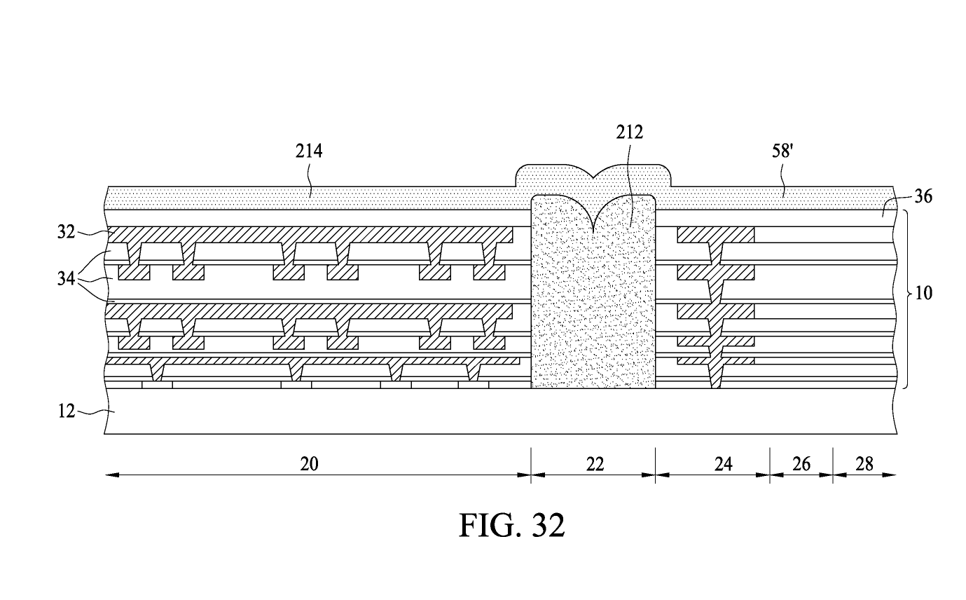

Referring to FIG. 31, the etching mask 60 is removed, and another dry etching process is performed to remove a portion of the dielectric layer 46 on the surface of the stack structure 10 completely, and the dielectric layer 46 remaining in the opening 44 serves as the supporting member 212 of the reinforcement structure 210. A deposition process is performed to form a dielectric layer 58′ to cover the surface of the circuit structure 20 and the supporting member 212 in the opening 44, and the dielectric layer 58′ on the circuit structure 20 serves as the roof 214, as shown in FIG. 32.

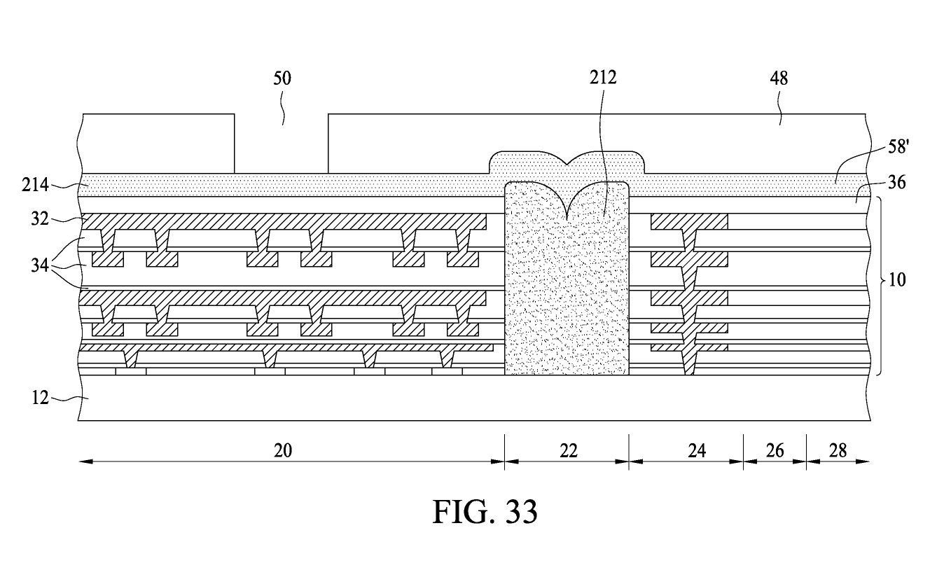

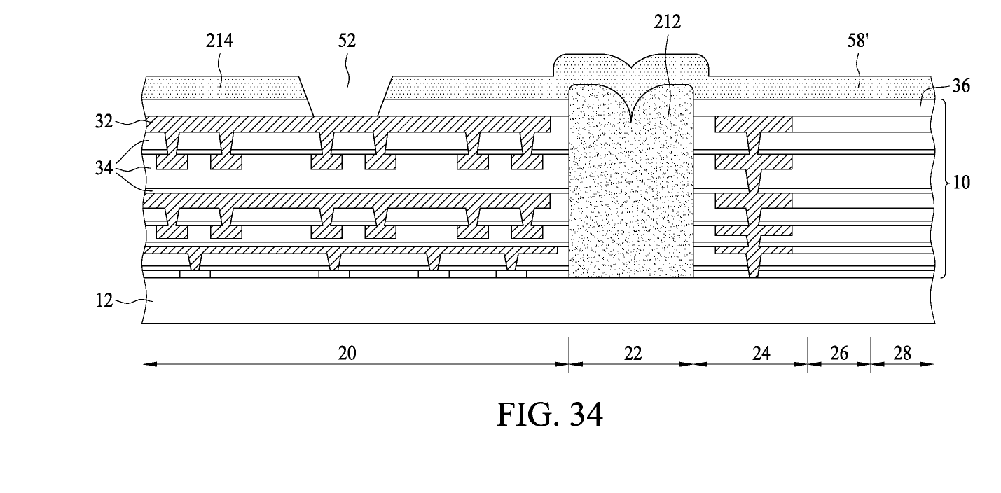

Referring to FIG. 33, an etching mask 48 including at least one aperture 50 is formed on the dielectric layer 58′, and the aperture 50 exposes a portion of the dielectric layer 58′ on the circuit structure 20, i.e., exposes a portion of the roof 214. In particular, the aperture 50 is used for patterning the size and the position of the bonding pad 54 on the roof 214, and the position and number of the aperture 50 correspond to those of the bonding pad 54. Subsequently, an etching process is performed to remove a portion of the dielectric layer 58′, the oxide layer 36 and the circuit structure 20 under the aperture 50 to form at least one opening 52 in the dielectric layer 58, and the opening 52 exposes the conductive lines 32 in the circuit structure 20, as shown in FIG. 34.

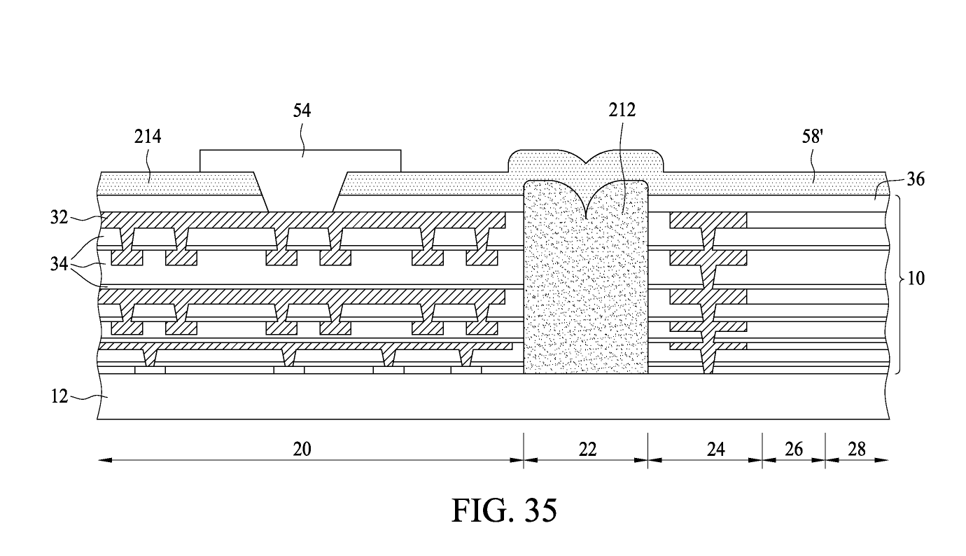

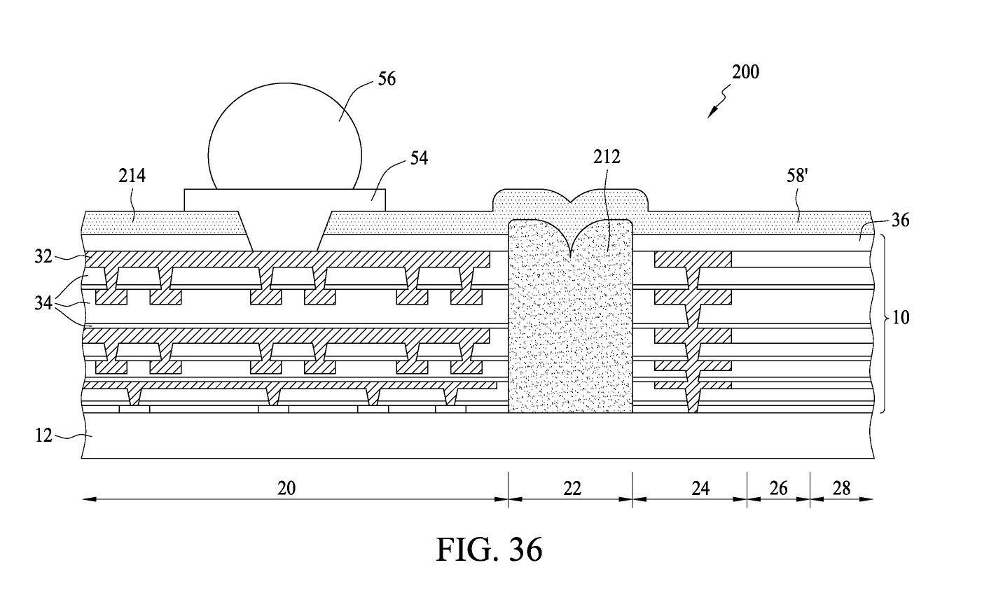

Referring to FIG. 35, a deposition process is performed to form a conductive layer (not shown in the drawing) covering the surface of the dielectric layer 58′ and filling the opening 52, and a portion of the conductive layer is removed from the surface of the dielectric layer 58′ to form the bonding pad 54 on the roof 214. Subsequently, a solder ball 56 is formed on the bonding pads 54 to complete the integrated circuit device 200, as shown in FIG. 36.

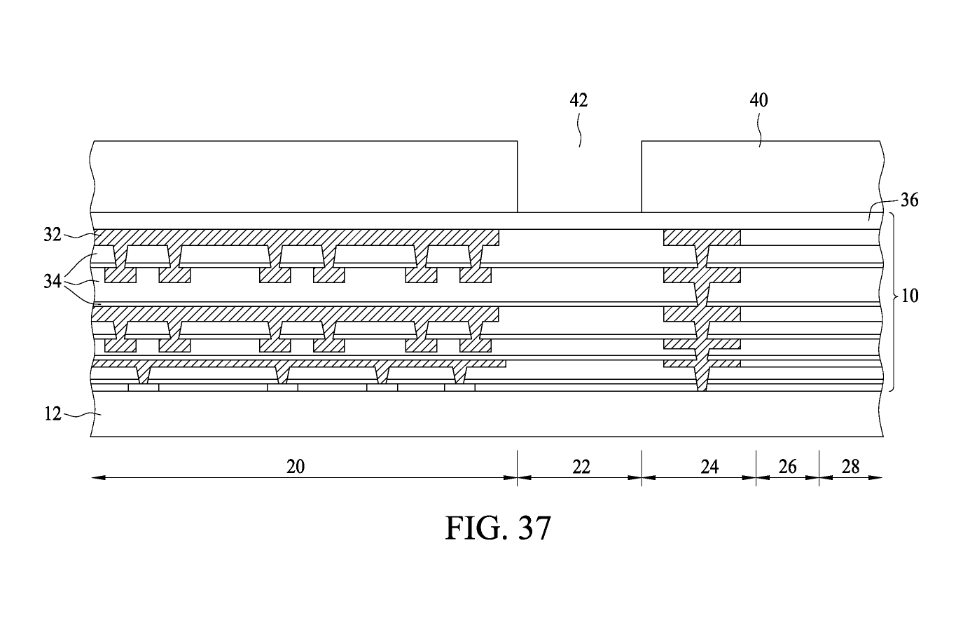

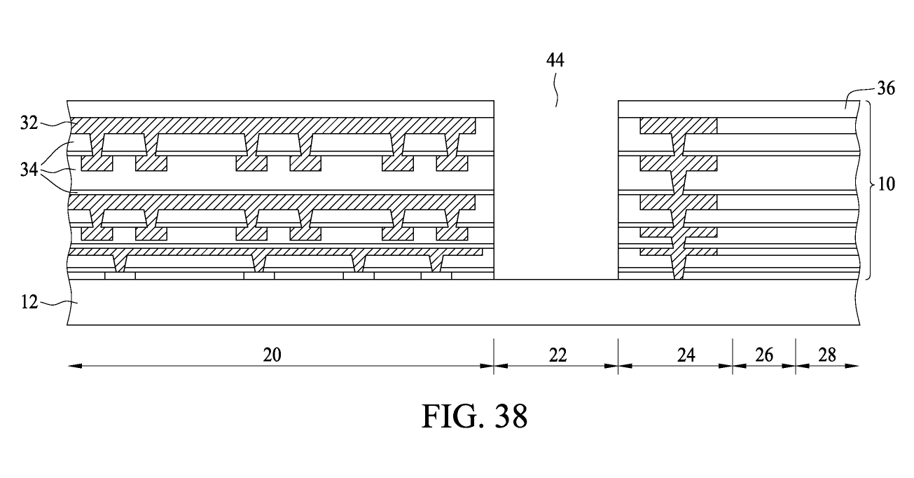

FIG. 37 to FIG. 46 illustrate a method for preparing an integrated circuit device 200 according to the fourth embodiment of the present invention. FIG. 37 to FIG. 46 are cross-sectional views along a cross-sectional line 1-1 in FIG. 8. An etching mask 40 including at least one aperture 42 is formed on the oxide layer 36, and the aperture 42 exposes the first buffer area 22 between the circuit structure 20 and the die seal 24. An etching process is performed to remove a portion of the stack structure 10 under the aperture 42 down to the surface of the substrate 12 to form at least one opening 44 in the stack structure 10, and the etching mask 40 is then removed, as shown in FIG. 38. In particular, the aperture 42 is used for patterning the size and the position of the supporting member 212 so that the position and the number of the aperture 42 correspond to those of the pillars 212B and the wall 212A of the supporting member 212.

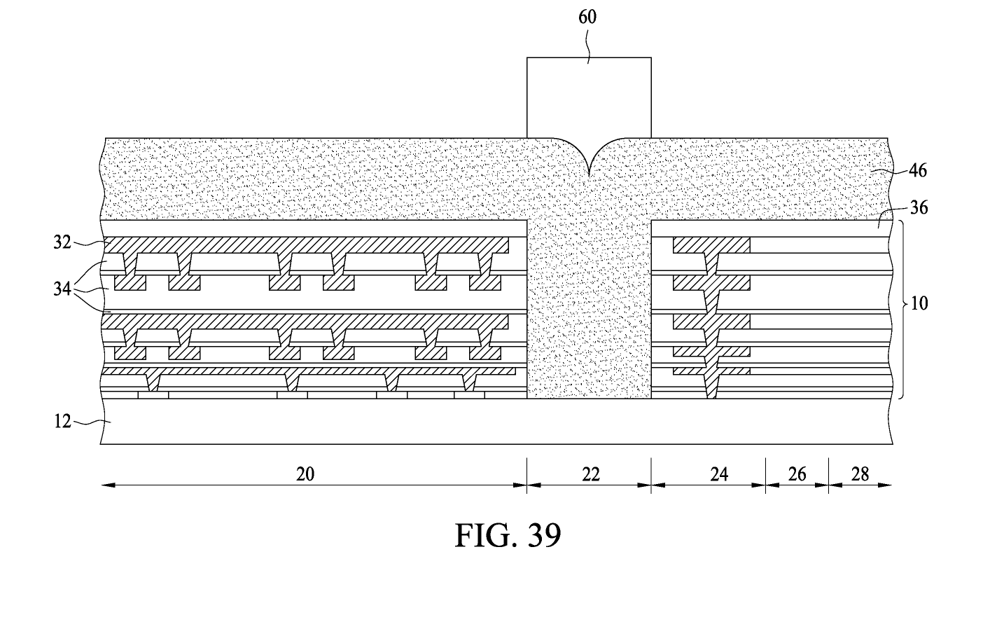

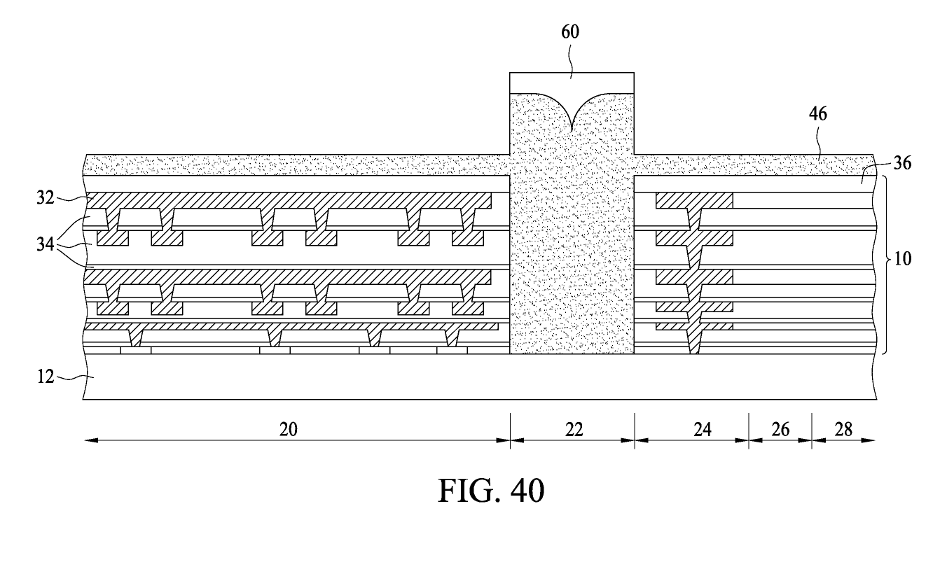

Referring to FIG. 39, a deposition process is performed to form a dielectric layer 46 covering the surface of the oxide layer 36 of the stack structure 10 and filling the opening 44 in the stack structure 10, and an etching mask 60 is formed to cover a portion of the dielectric layer 46 on the opening 44. Subsequently, a dry etching process is performed to remove a portion of the dielectric layer 46 not covered by the etching mask 60, as shown in FIG. 40.

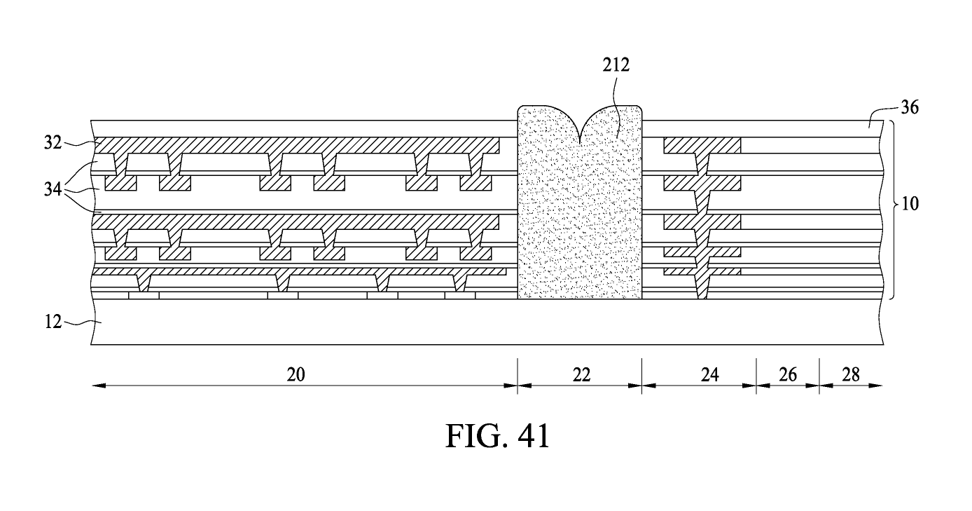

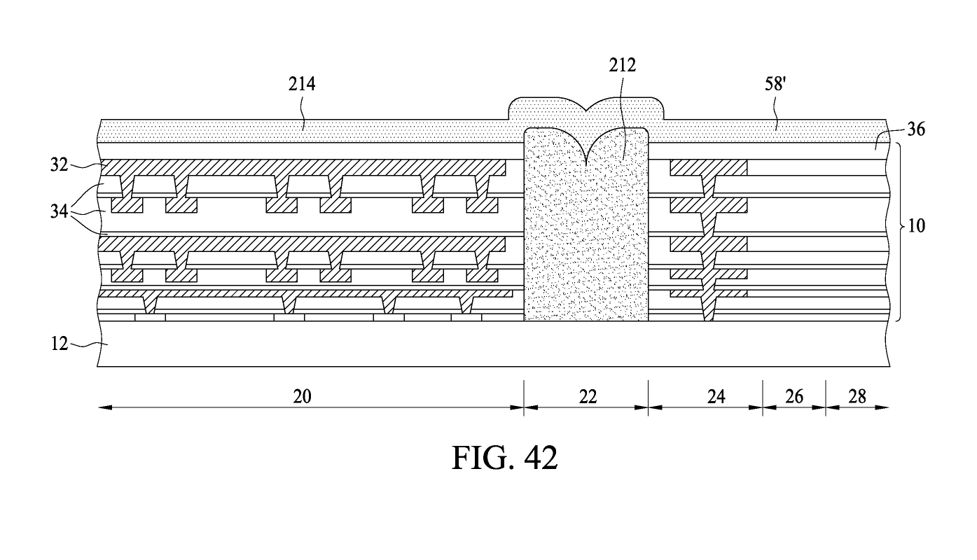

Referring to FIG. 41, the etching mask 60 is removed, and another dry etching process is performed to remove a portion of the dielectric layer 46 on the surface of the stack structure 10 completely, and the dielectric layer 46 remaining in the opening 44 serves as the supporting member 212 of the reinforcement structure 210. A deposition process is performed to form a dielectric layer 58′ to cover the surface of the circuit structure 20 and the supporting member 212 in the opening 44, and the dielectric layer 58′ on the circuit structure 20 serves as the roof 214 of the reinforcement structure 210, as shown in FIG. 42.

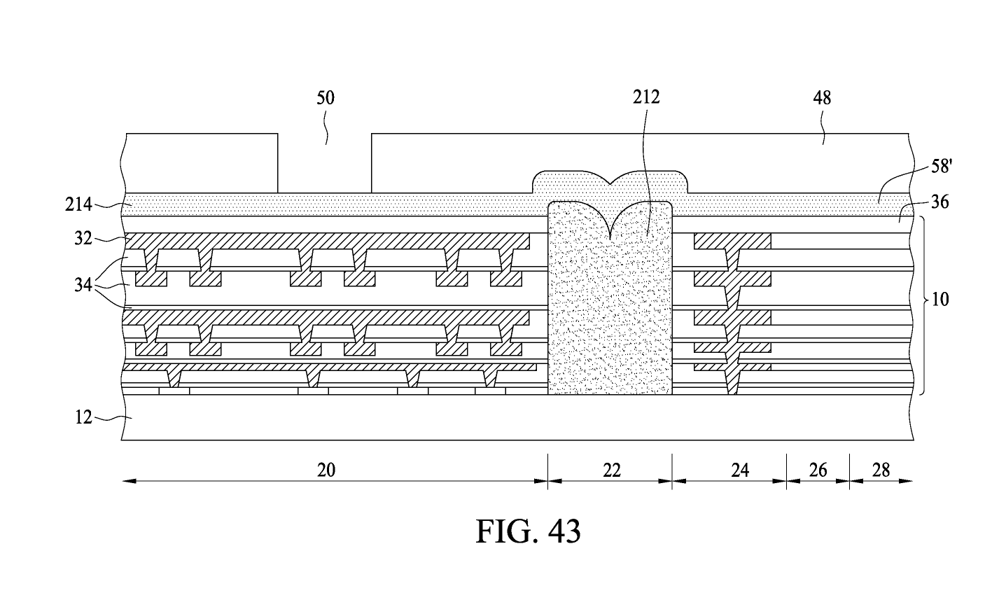

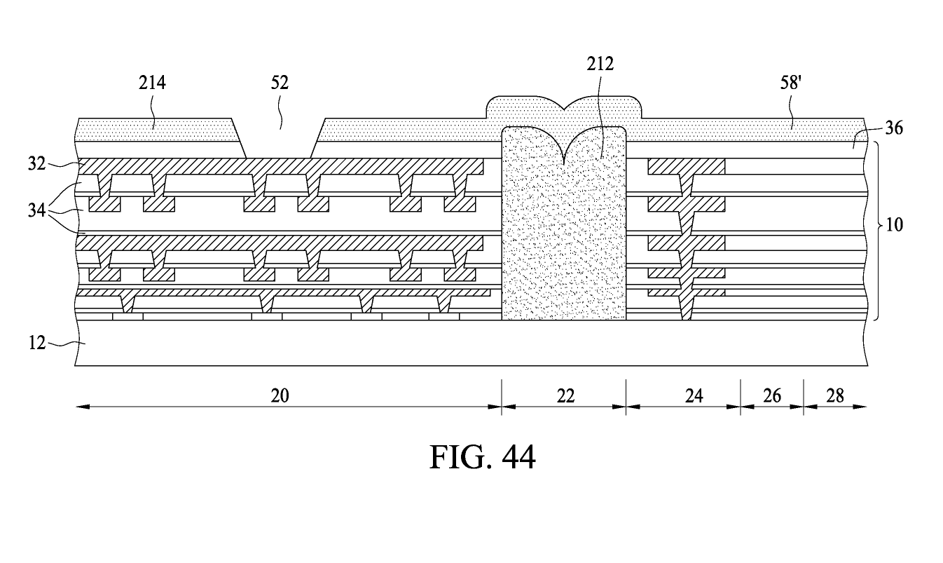

Referring to FIG. 43, an etching mask 48 including at least one aperture 50 is formed on the dielectric layer 58′, and the aperture 50 exposes a portion of the dielectric layer 58′ on the circuit structure 20, i.e., exposes a portion of the roof 214. In particular, the aperture 50 is used for patterning the size and the position of the bonding pad 54 on the roof 214, and the position and number of the aperture 50 correspond to those of the bonding pad 54. Subsequently, an etching process is performed to remove a portion of the dielectric layer 58′, the oxide layer 36 and the circuit structure 20 under the aperture 50 to form at least one opening 52 in the dielectric layer 58, the opening 52 exposes the conductive lines 32 in the circuit structure 20, and the etching mask 48 is then removed, as shown in FIG. 44.

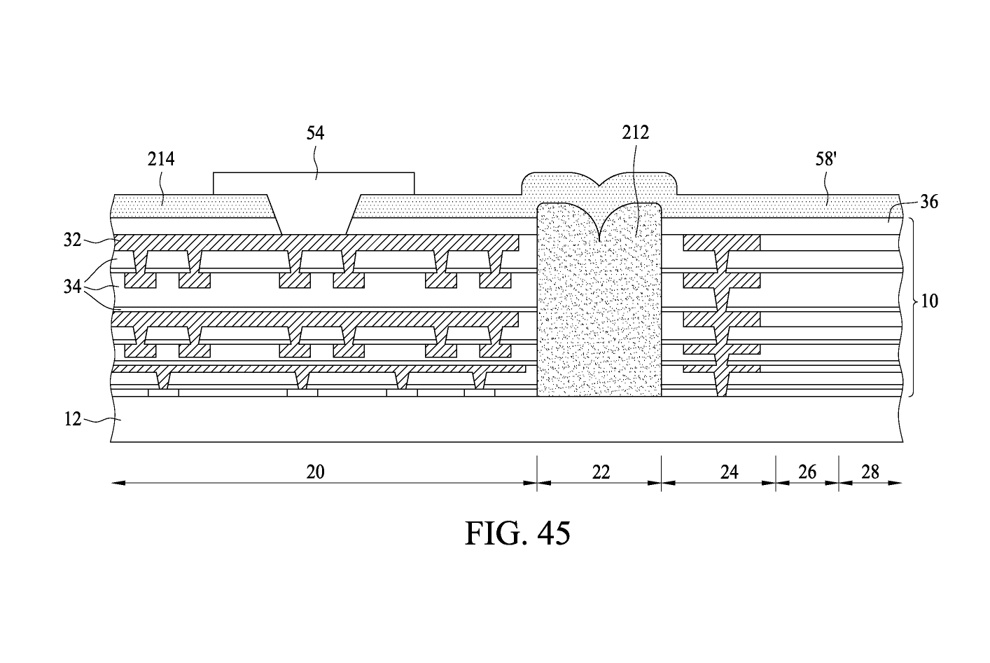

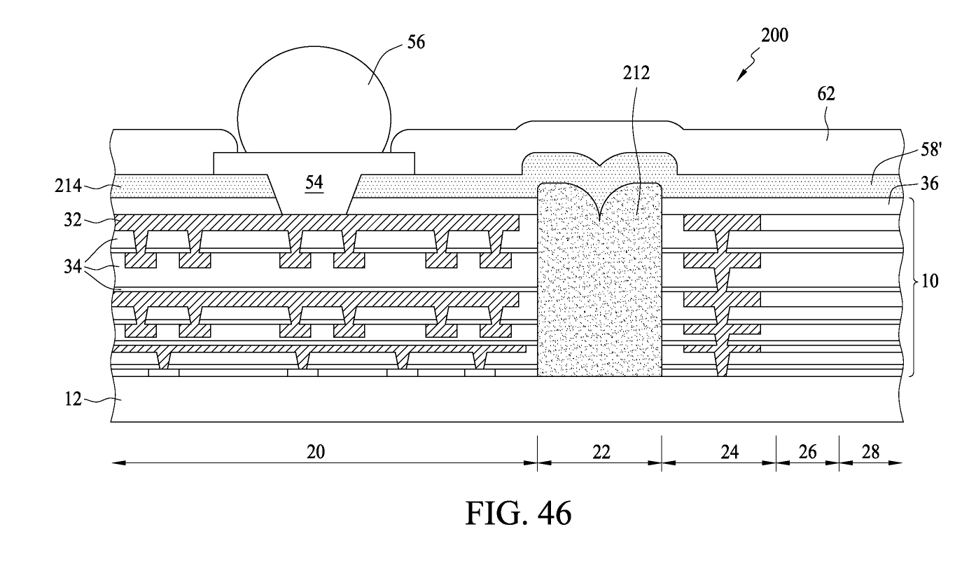

Referring to FIG. 45, a deposition process is performed to form a conductive layer (not shown in the drawing) covering the surface of the dielectric layer 58′ and filling the opening 52, and a portion of the conductive layer is removed from the surface of the dielectric layer 58 to form the bonding pad 54 on the roof 214. Subsequently, a sealing layer 62 including polyimide is formed to cover the bonding pad 54 and the roof 214, a portion of the sealing layer 62 is then removed from the surface of the bonding pad 54, and a solder ball 56 is formed on the bonding pads 54 later to complete the integrated circuit device 200, as shown in FIG. 46.

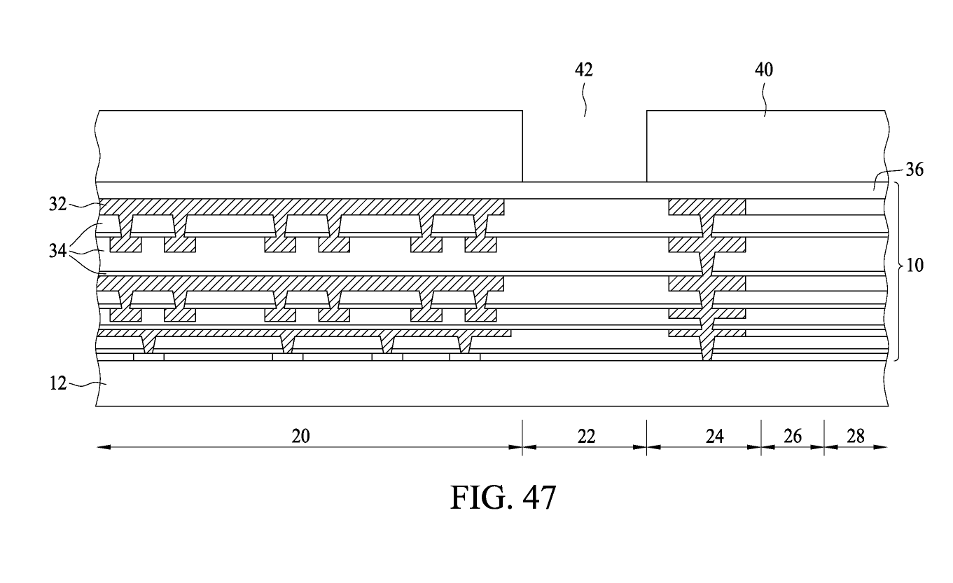

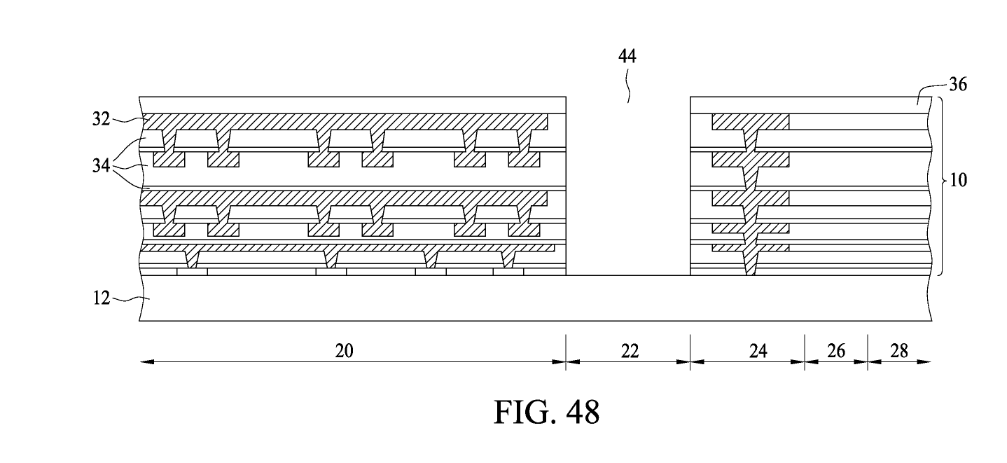

FIG. 47 to FIG. 54 illustrate a method for preparing an integrated circuit device 200 according to the fifth embodiment of the present invention. FIG. 47 to FIG. 54 are cross-sectional views along a cross-sectional line 1-1 in FIG. 8. An etching mask 40 including at least one aperture 42 is formed on the oxide layer 36, and the aperture 42 exposes the first buffer area 22 between the circuit structure 20 and the die seal 24. An etching process is performed to remove a portion of the stack structure 10 under the aperture 42 down to the surface of the substrate 12 to form at least one opening 44 in the stack structure 10, and the etching mask 40 is then removed, as shown in FIG. 48. In particular, the aperture 42 is used for patterning the size and the position of the supporting member 212 so that the position and the number of the aperture 42 correspond to those of the pillars 212B and the wall 212A of the supporting member 212.

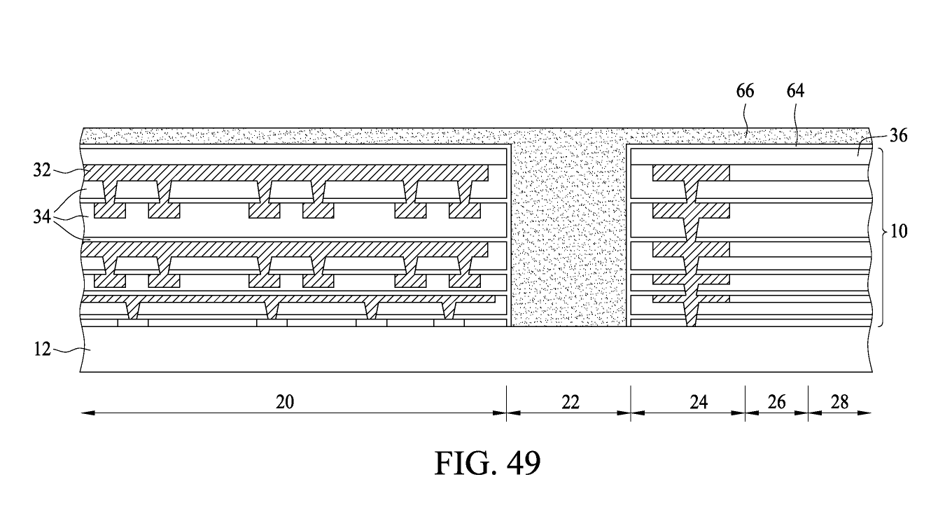

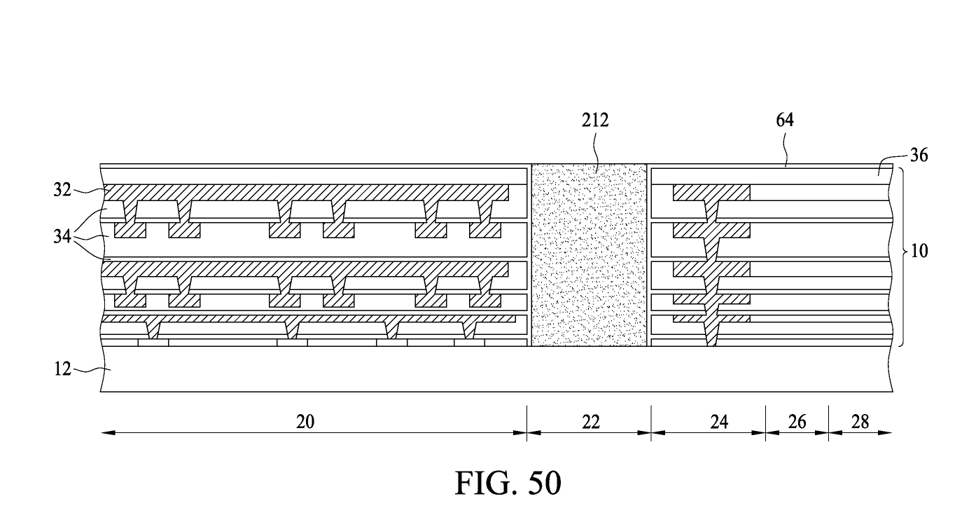

Referring to FIG. 49, a deposition process is performed to form a liner layer 64 including silicon oxide covering the inner surface of the opening 44 and the surface of the stack structure 10, and spin-coating process is performed to form a dielectric layer 66 on the liner layer 64. Subsequently, an etching process is performed to remove a portion of the dielectric layer 66 from the liner layer 64 on the surface of the stack structure 10 completely, and the dielectric layer 66 remaining in the opening 44 serves as the supporting member 212 of the reinforcement structure 210, as shown in FIG. 50.

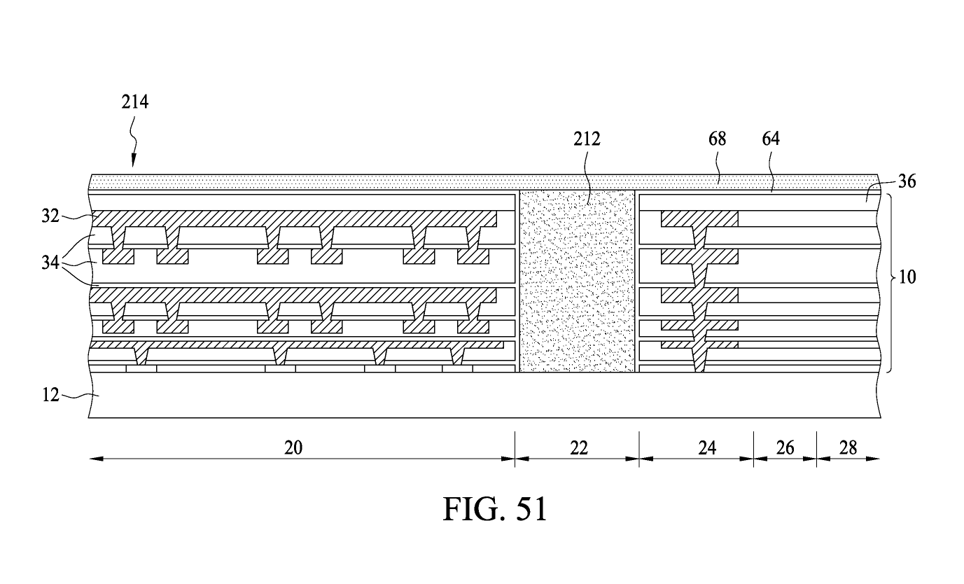

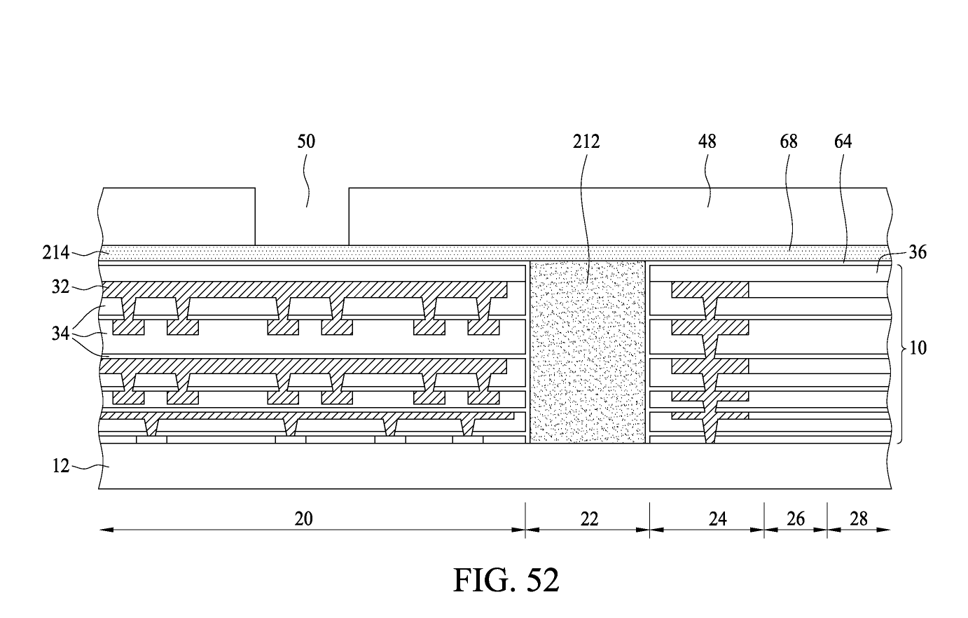

Referring to FIG. 51, a deposition process is performed to form a dielectric layer 68 to cover the surface of the circuit structure 20 and the supporting member 212 in the opening 44, and the dielectric layer 68 on the circuit structure 20 serves as the roof 214 of the reinforcement structure 210. An etching mask 48 including at least one aperture 50 is formed on the dielectric layer 58, and the aperture 50 exposes a portion of the dielectric layer 58 on the circuit structure 20, i.e., exposes a portion of the roof 214, as shown in FIG. 52. In particular, the aperture 50 is used for patterning the size and the position of the bonding pad 54 on the roof 214, and the position and number of the aperture 50 correspond to those of the bonding pad 54.

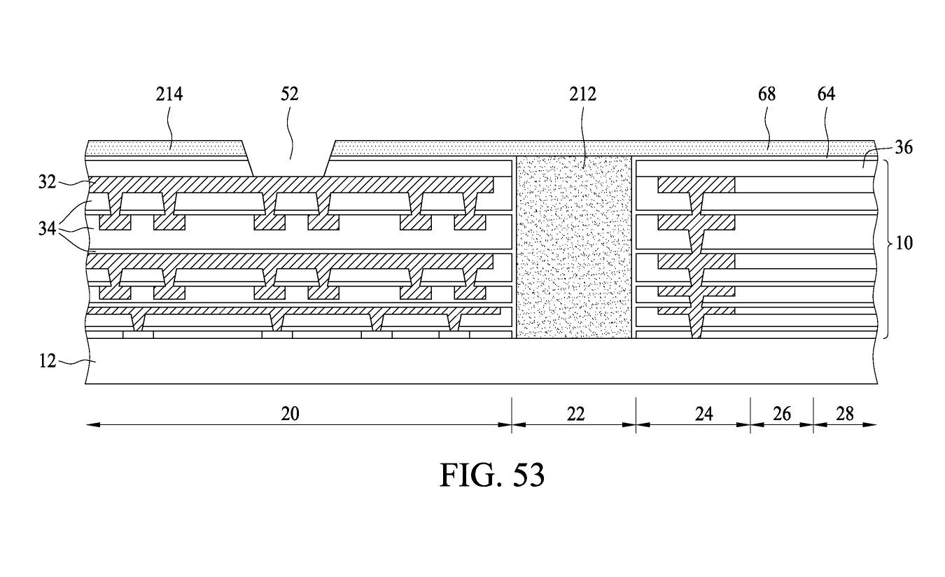

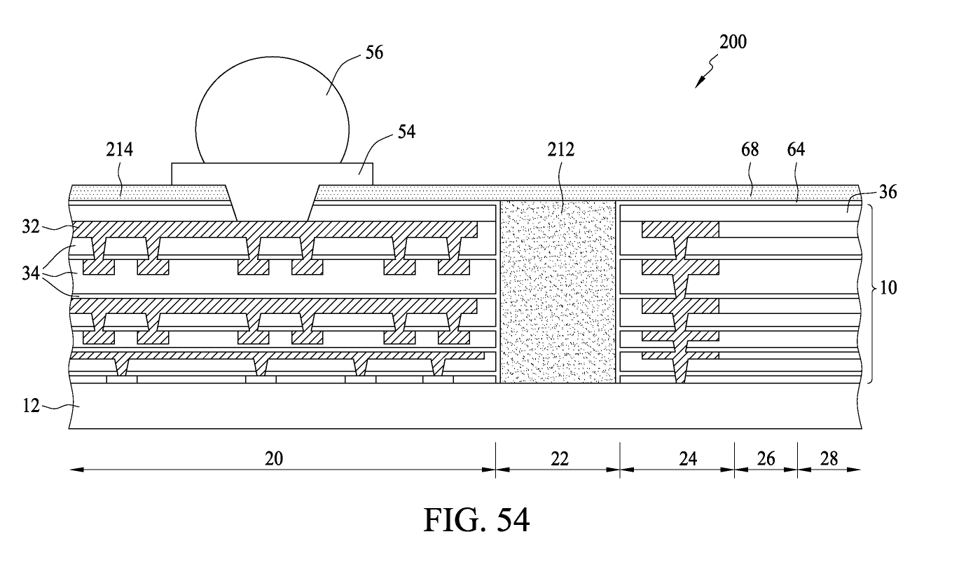

Referring to FIG. 53, an etching process is performed to remove a portion of the dielectric layer 68, the oxide layer 36 and the circuit structure 20 under the aperture 50 to form at least one opening 52 in the dielectric layer 68, the opening 52 exposes the conductive lines 32 in the circuit structure 20, and the etching mask 48 is then removed. A deposition process is performed to form a conductive layer (not shown in the drawing) covering the surface of the dielectric layer 58 and filling the opening 52, a portion of the conductive layer is then removed from the surface of the dielectric layer 68 to form the bonding pad 54 on the roof 214, and a solder ball 56 is formed on the bonding pads 54 later to complete the integrated circuit device 200, as shown in FIG. 54.

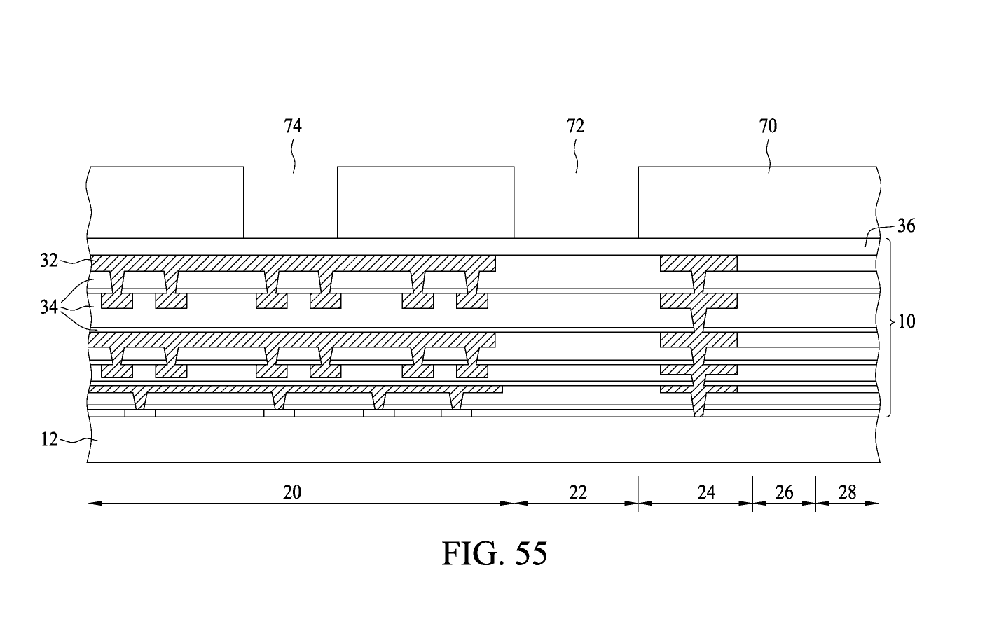

FIG. 55 to FIG. 61 illustrate a method for preparing an integrated circuit device 200 according to the sixth embodiment of the present invention. FIG. 55 to FIG. 61 are cross-sectional views along a cross-sectional line 1-1 in FIG. 8. An etching mask 70 including at least one aperture 72 and at least one aperture 74 is formed on the oxide layer 36, and the aperture 72 exposes the oxide layer 36 on the first buffer area 22 between the circuit structure 20 and the die seal 24 and the aperture 74 exposes the oxide layer 36 on the circuit structure 20. In particular, the aperture 72 is used for patterning the size and the position of the supporting member 212 so that the position and the number of the aperture 42 correspond to those of the pillars 212B and the wall 212A of the supporting member 212.

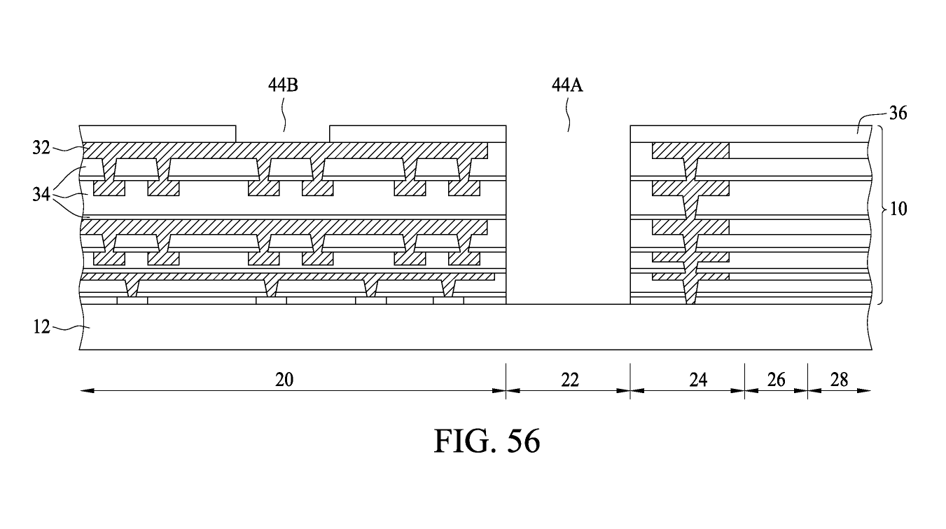

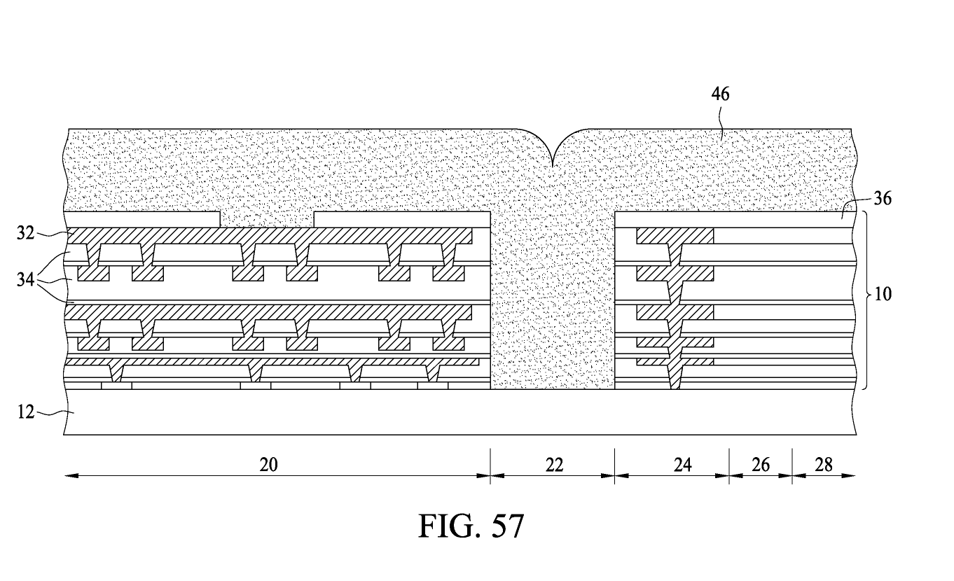

Referring to FIG. 56, an etching process is performed to remove a portion of the stack structure 10 under the aperture 72 down to the surface of the substrate 12 to form at least one opening 44A in the stack structure 10 and a second opening 44B exposing the conductive lines 32 in the circuit structure 20, and the etching mask 40 is then removed. Subsequently, a deposition process is performed to form a dielectric layer 46 covering the surface of the oxide layer 36 of the stack structure 10 and filling the opening 44A and the second opening 44B in the stack structure 10, as shown in FIG. 57.

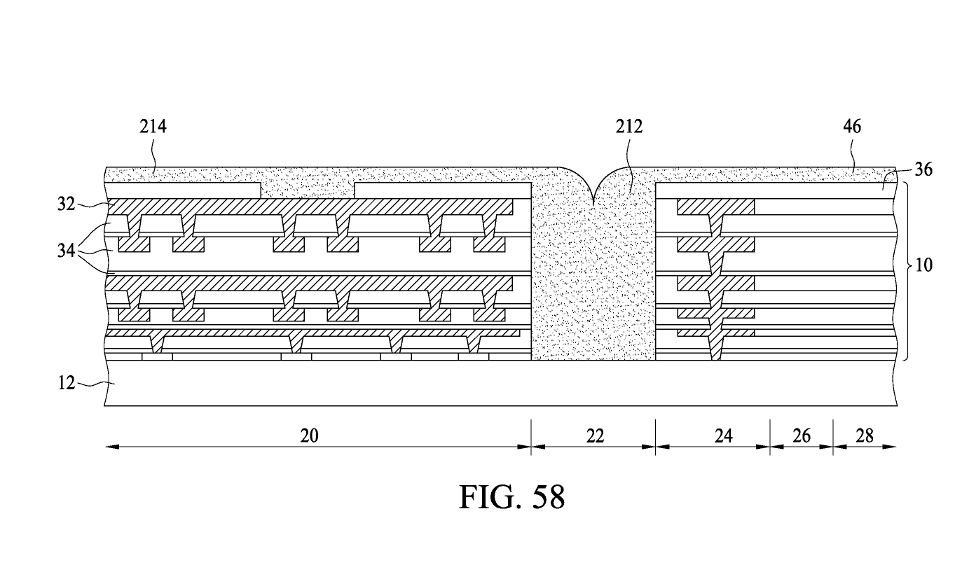

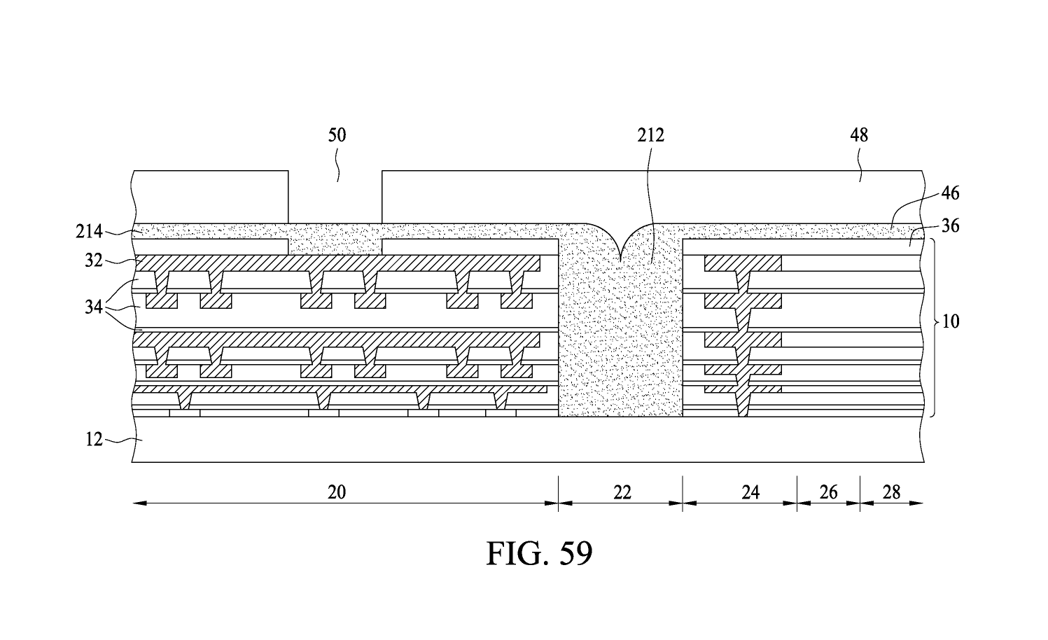

Referring to FIG. 58, an etch back process is performed to reduce the thickness of the dielectric layer 46 on the surface of the oxide layer 36 of the stack structure 10. The dielectric layer 46 remaining on the surface of the circuit structure 20 serves as the roof 214 and the first dielectric layer 46 remaining in the opening 44A serves as the supporting member 212 of the reinforcement structure 210. Subsequently, an etching mask 48 including at least one aperture 50 is formed on the dielectric layer 46, and the aperture 50 exposes a portion of the dielectric layer 46 on the circuit structure 20, i.e., exposes a portion of the roof 214, as shown in FIG. 59. In particular, the aperture 50 is used for patterning the size and the position of the bonding pad 54 on the roof 214, and the position and number of the aperture 50 correspond to those of the bonding pad 54.

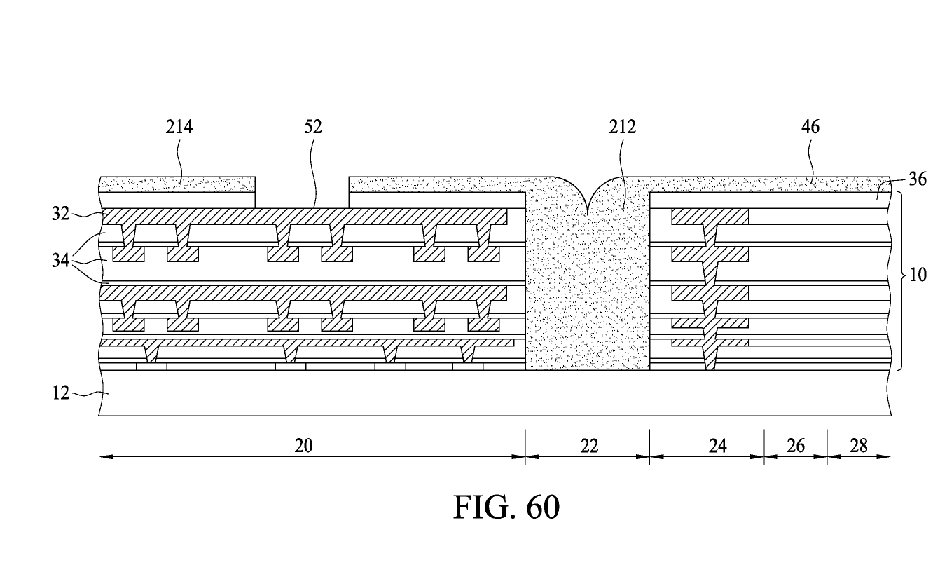

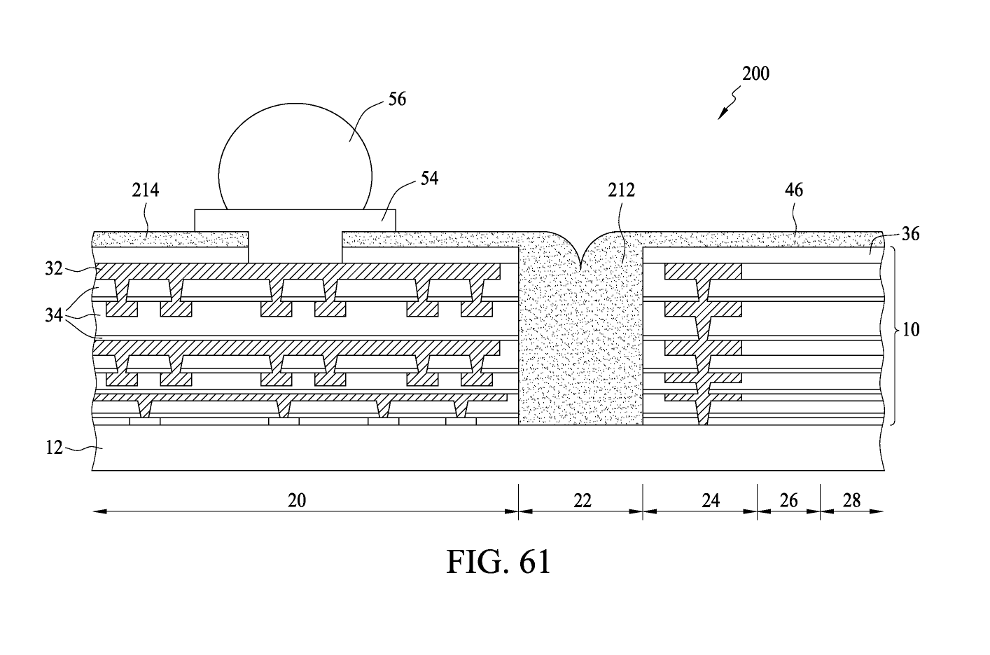

Referring to FIG. 60, an etching process is performed to remove a portion of the dielectric layer 46, the oxide layer 36 and circuit structure 20 under the aperture 50 to form at least one opening 52 in the dielectric layer 46, the opening 52 exposes the conductive lines 32 in the circuit structure 20, and the etching mask 48 is then removed. Subsequently, a conductive layer (not shown in the drawing) is formed to cover the surface of the dielectric layer 46 and fills the opening 52, and a portion of the conductive layer is then removed from the surface of the dielectric layer 46 to form a bonding pad 54 on the roof 214 and electrically connect to the conductive lines 32 in the circuit structure 20. A solder ball 56 is formed on the bonding pads 54 to complete the integrated circuit device 200, as shown in FIG. 61.

The above-described embodiments of the present invention are intended to be illustrative only. Numerous alternative embodiments may be devised by those skilled in the art without departing from the scope of the following claims.

What is claimed is:

1. A method for preparing an integrated circuit device, comprising the steps of:
forming a stack structure on a substrate, wherein the stack structure includes a circuit structure having conductive lines therein;
forming a reinforcement structure in the circuit structure, wherein the reinforcement structure includes at least one supporting member and a roof covering the supporting member and the circuit structure; and
forming at least one bonding pad on the roof, wherein the bonding pad is electrically connected to the conductive lines.

2. The method for preparing an integrated circuit device as claimed in claim 1, wherein the step of forming a reinforcement structure in the stack structure includes:
forming at least one first opening in the stack structure; and
forming a first dielectric layer covering the surface of the stack structure and filling the first opening.

3. The method for preparing an integrated circuit device as claimed in claim 2, wherein the step of forming at least one first opening in the stack structure includes:
forming an etching mask including at least one aperture on the stack structure; and
performing an etching process to remove a portion of the stack structure under the aperture down to the substrate to form the first opening.

4. The method for preparing an integrated circuit device as claimed in claim 2, wherein the step of forming a reinforcement structure in the stack structure further includes performing an etch back process to reduce the thickness of the first dielectric layer on the surface of the stack structure.

5. The method for preparing an integrated circuit device as claimed in claim 4, wherein the first dielectric layer on the surface of the circuit structure serves as the roof and the first dielectric layer in the first opening serves as the supporting member.

6. The method for preparing an integrated circuit device as claimed in claim 5, wherein the step of forming at least one bonding pad on the roof includes:
forming at least one second opening in the first dielectric layer, wherein the second opening exposes the conductive lines in the circuit structure;
forming a conductive layer covering the surface of the first dielectric layer and filling the second opening; and
removing a portion of the conductive layer from the surface of the first dielectric layer to form the bonding pad on the roof.

7. The method for preparing an integrated circuit device as claimed in claim 4, wherein the etch back process removes the first dielectric layer from the surface of the stack structure completely, and the first dielectric layer remaining in the first opening serves as the supporting member.

8. The method for preparing an integrated circuit device as claimed in claim 7, wherein the step of forming a reinforcement structure in the stack structure further includes forming a second dielectric layer to cover the surface of the circuit structure and the supporting member in the first opening to form the roof.

9. The method for preparing an integrated circuit device as claimed in claim 8, wherein the step of forming at least one bonding pad on the roof includes:
forming at least one second opening in the second dielectric layer, wherein the second opening exposes the conductive lines in the circuit structure;
forming a conductive layer covering the surface of the second dielectric layer and filling the second opening; and
removing a portion of the conductive layer from the surface of the second dielectric layer to form the bonding pad on the roof.

10. The method for preparing an integrated circuit device as claimed in claim 1, wherein the step of forming a reinforcement structure in the stack structure further includes:
forming at least one first opening in the stack structure;
forming a first dielectric layer covering the surface of the stack structure and filling the first opening;
forming an etching mask covering a portion of the first dielectric layer on the first opening;
performing a first etching process to remove a portion of the first dielectric layer not covered by the etching mask;
removing the etching mask; and
performing a second etching process to remove a portion of the first dielectric layer from the surface of the stack structure, wherein the first dielectric layer remaining in the first opening serves as the supporting member.

11. The method for preparing an integrated circuit device as claimed in claim 10, wherein the step of forming a reinforcement structure in the stack structure further includes a step of forming a second dielectric layer to cover the surface of the stack structure and the supporting member in the first opening, and the second dielectric layer forms the roof.

12. The method for preparing an integrated circuit device as claimed in claim 11, wherein the step of forming at least one bonding pad on the roof includes:
forming at least one second opening in the second dielectric layer, wherein the second opening exposes the conductive lines in the circuit structure;
forming a conductive layer on the surface of the second dielectric layer and in the second opening; and
removing a portion of the conductive layer from the surface of the second dielectric layer to form the bonding pad on the roof.

13. The method for preparing an integrated circuit device as claimed in claim 12, further comprising the steps of:
forming a sealing layer covering the bonding pad and the roof; and
removing a portion of the sealing layer from the surface of the bonding pad.

14. The method for preparing an integrated circuit device as claimed in claim 1, wherein the step of forming a reinforcement structure in the stack structure includes:
forming at least one first opening in the stack structure;
forming a liner layer covering the inner surface of the first opening and the surface of the stack structure;
forming the supporting member in the first opening; and
forming the roof on the liner layer and the supporting member.

15. The method for preparing an integrated circuit device as claimed in claim 14, wherein the step of forming at least one first opening in the stack structure includes:
forming an etching mask including at least one aperture on the stack structure; and
performing an etching process to remove a portion of the stack structure under the aperture down to the substrate to form the first opening.

16. The method for preparing an integrated circuit device as claimed in claim 14, wherein the step of forming the supporting member in the first opening includes:
forming a first dielectric layer on the liner layer; and
removing a portion of the first dielectric layer from the liner layer on the surface of the stack structure.

17. The method for preparing an integrated circuit device as claimed in claim 16, wherein the first dielectric layer is formed on the liner layer by a spin-coating process.

18. The method for preparing an integrated circuit device as claimed in claim 16, wherein the step of forming at least one bonding pad on the roof includes:
forming at least one second opening in the roof, wherein the second opening exposes the conductive lines in the circuit structure;
forming a conductive layer on the surface of the roof and in the second opening; and
removing a portion of the conductive layer from the surface of the roof to form the bonding pad on the roof.

19. The method for preparing an integrated circuit device as claimed in claim 1, wherein the step of forming a reinforcement structure in the stack structure includes:
forming an etching mask having at least one first aperture and at least one second aperture;
performing a first etching process to form a first opening under the first aperture and at least one second opening under the second apertures, wherein the first opening exposes the substrate and the second opening exposes the conductive lines in the circuit structure; and
forming a first dielectric layer covering the surface of the stack structure and filling the first opening and the second opening.

20. The method for preparing an integrated circuit device as claimed in claim 19, wherein the step of forming a reinforcement structure in the stack structure further includes performing an etch back process to reduce the thickness of the first dielectric layer on the surface of the stack structure.

21. The method for preparing an integrated circuit device as claimed in claim 20, wherein a portion of the first dielectric layer remains on the surface of the circuit structure and in the first opening after the etch back process, and the first dielectric layer on the surface of the circuit structure serves as the roof and the first dielectric layer in the first opening serves as the supporting member.

22. The method for preparing an integrated circuit device as claimed in claim 21, wherein the step of forming at least one bonding pad on the roof includes:
removing a portion of the first dielectric layer from the second opening to expose the conductive lines in the circuit structure;
forming a conductive layer on the surface of the first dielectric layer and in the second opening; and
removing a portion of the conductive layer from the surface of the first dielectric layer to form the bonding pad.
